(19) United States
(12) Patent Application Publication
(10) Pub. No.: US 2024/0405041 A1
(43) Pub. Date: Dec. 5, 2024

(54) IMAGE SENSOR

(71) Applicant: Samsung Electronics Co., Ltd., Suwon-si (KR)

(72) Inventors: Jae Ho KIM, Suwon-si (KR); Hyeyun PARK, Suwon-si (KR); Gijae KANG, Suwon-si (KR); Seonghoon KO, Suwon-si (KR); Jin Soak KIM, Suwon-si (KR); Wook LEE, Suwon-si (KR); Joohyun JEON, Suwon-si (KR); Guhyun KWON, Suwon-si (KR)

(73) Assignee: Samsung Electronics Co., Ltd., Suwon-si (KR)

(21) Appl. No.: 18/639,136

(22) Filed: Apr. 18, 2024

(30) Foreign Application Priority Data
Jun. 5, 2023 (KR) 10-2023-0072460

(51) Int. Cl. H01L 27/146

(52) U.S. Cl. CPC H01L 27/14614; H01L 27/14645

(57) ABSTRACT

An image sensor that includes a substrate including a photoelectric conversion region, a semiconductor pattern on the substrate, a gate electrode on the semiconductor pattern, and a gate insulating layer between the semiconductor pattern and the gate electrode. The semiconductor pattern includes a first sub pattern including a first source/drain region, a second sub pattern including a second source/drain region, and a third sub pattern between the first sub pattern and the second sub pattern. The gate electrode is on the third sub pattern. The first sub pattern, the second sub pattern, and the third sub pattern extend along different directions.

### CROSS-REFERENCE TO RELATED APPLICATIONS

This application claims priority under 35 U.S.C. § 119 to Korean Patent Application No. 10-2023-0072460 filed on Jun. 5, 2023, in the Korean Intellectual Property Office, the disclosure of which is incorporated by reference herein in its entirety.

### BACKGROUND

Embodiments of the present disclosure described herein relate to image sensors.

An image sensor is a device that converts an optical image signal into an electrical signal, and may be characterized as a charge coupled device (CCD) image sensor or a complementary metal oxide semiconductor (CMOS) image sensor. An image sensor includes a plurality of pixels. Each pixel includes a light-receiving region that receives incident light and converts it into an electrical signal, and a pixel circuit that outputs a pixel signal using charge generated in the light-receiving region.

Recently, as the degree of integration of image sensors has increased, the size of pixels are getting smaller. There is a problem in that the quality of the image sensor is degraded due to image transfer delay or the like depending on the arrangement and shape of components in the pixel as implemented to be smaller.

### SUMMARY

Embodiments of the present disclosure provide a pixel with improved trap characteristics, and improved noise characteristics.

Embodiments of the inventive concepts provide an image sensor that includes a substrate including a photoelectric conversion region; a semiconductor pattern on the substrate; a gate electrode on the semiconductor pattern; and a gate insulating layer between the semiconductor pattern and the gate electrode. The semiconductor pattern includes a first sub pattern including a first source/drain region, a second sub pattern including a second source/drain region, and a third sub pattern between the first sub pattern and the second sub pattern. The gate electrode is on the third sub pattern, and the first sub pattern, the second sub pattern, and the third sub pattern extend along different directions.

Embodiments of the inventive concepts further provide an image sensor that includes a first pixel; and a second pixel. Each of the first and second pixels includes a substrate including a photoelectric conversion region and a floating diffusion region, a semiconductor pattern on the substrate, a gate electrode on the semiconductor pattern, and a gate insulating layer between the semiconductor pattern and the gate electrode. The semiconductor pattern of each of the first and second pixels includes a first sub pattern including a first source/drain region, a second sub pattern including a second source/drain region, and a third sub pattern between the first sub pattern and the second sub pattern. The first sub pattern, the second sub pattern, and the third sub pattern extend in different directions. The gate electrode is on a side of the third sub pattern. The floating diffusion region of the first and second pixels are respectively electrically connected to the gate electrode of the first pixel and the gate electrode of the second pixel.

### BRIEF DESCRIPTION OF THE DRAWINGS

The above and other objects and features of the present disclosure will become apparent by describing in detail embodiments thereof with reference to the accompanying drawings.

FIG. 1 is a block diagram of an image sensor according to example embodiments.

FIG. 2 is a plan view of the pixel array of FIG. 1.

FIG. 3 is an equivalent circuit diagram of the pixel group of FIG. 1.

FIG. 4A is a plan view illustrating pixels of an image sensor according to example embodiments.

FIG. 4B is a cross-sectional view taken along the line A1-A1′ of FIG. 4A.

FIG. 4C is a cross-sectional view taken along the line A2-A2′ of FIG. 4A.

FIG. 4D is a plan view illustrating the semiconductor pattern of FIG. 4A.

FIG. 5A is a plan view illustrating pixels of an image sensor according to example embodiments.

FIG. 5B is a cross-sectional view taken along line B1-B1′ of FIG. 5A.

FIG. 6A is a plan view illustrating pixels of an image sensor according to example embodiments.

FIG. 6B is a cross-sectional view taken along line C1-C1′ of FIG. 6A.

FIG. 6C is a cross-sectional view taken along line C2-C2′ of FIG. 6A.

FIG. 6D is a plan view illustrating the semiconductor pattern of FIG. 6A.

FIG. 7A is a plan view illustrating pixels of an image sensor according to example embodiments.

FIG. 7B is a plan view illustrating the semiconductor pattern of FIG. 7A.

FIG. 8 is a plan view illustrating pixels of an image sensor according to example embodiments.

FIG. 9A is a plan view illustrating pixels of an image sensor according to example embodiments.

FIG. 9B is a plan view illustrating the semiconductor pattern of FIG. 9A.

FIG. 10A is a plan view illustrating a pixel group of an image sensor according to example embodiments.

FIG. 10B is a cross-sectional view taken along the line G1-G1′ of FIG. 10A.

FIG. 10C is a cross-sectional view taken along line G2-G2′ of FIG. 10A.

FIG. 10D is a plan view illustrating the semiconductor patterns of FIG. 10A.

FIGS. 11, 12, 13, 14 and 15 are plan views illustrating pixel groups of an image sensors according to example embodiments.

FIG. 16A is a plan view illustrating a pixel group of an image sensor according to example embodiments.

FIG. 16B is a cross-sectional view taken along the line H1-H1′ of FIG. 16A.

### DETAILED DESCRIPTION

Below, example embodiments of the present disclosure will be described in detail and clearly to such an extent that one of ordinary skill in the art may easily implement the inventive concepts.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

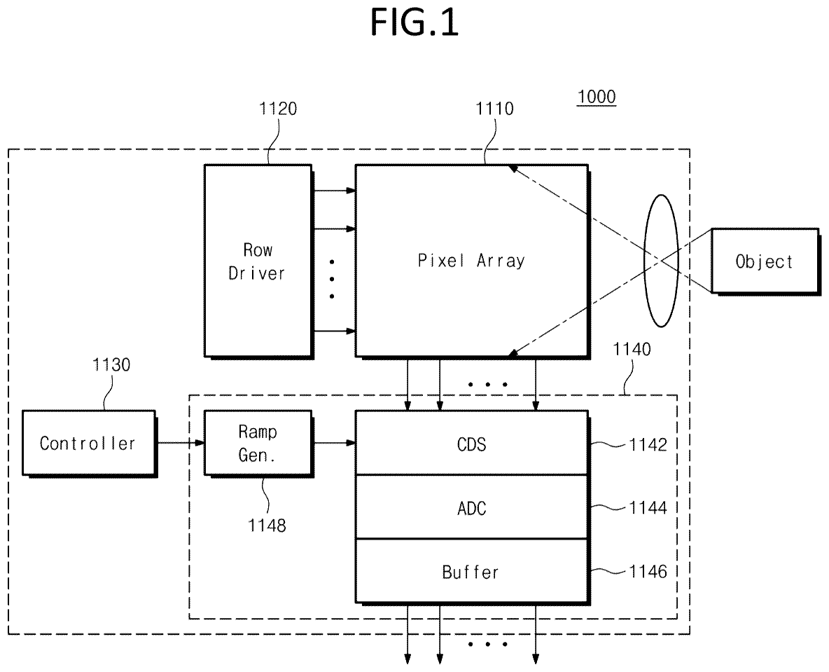

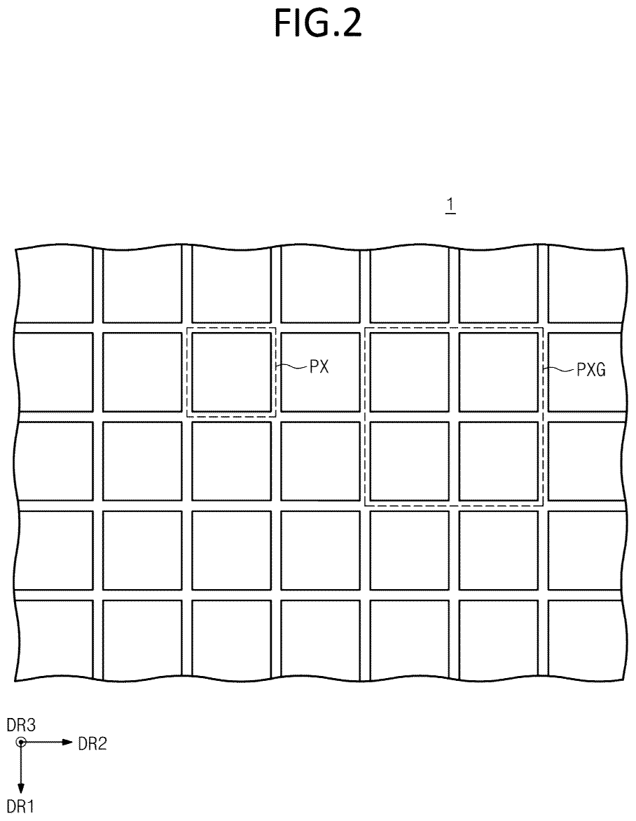

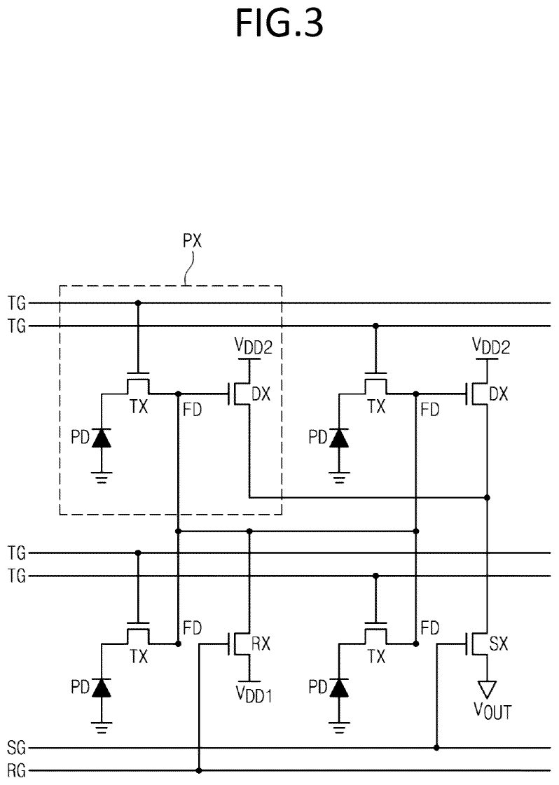

FIG. 1 is a block diagram of an image sensor according to example embodiments. FIG. 2 is a plan view of a pixel array of FIG. 1. FIG. 3 is an equivalent circuit diagram of a pixel group of FIG. 1.

Referring to FIG. 1, an image sensor 1000 may be provided. The image sensor 1000 may be mounted in an electronic device having an image or light sensing function. For example, the electronic device may be a camera, a smartphone, a wearable device, the Internet of Things (IoT), a tablet PC (Personal Computer), a PDA (Personal Digital Assistant), a PMP (portable multimedia player), or a navigation device. The image sensor 1000 may be mounted in electronic devices provided as components in various devices (e.g., vehicles, furniture, manufacturing facilities, doors, various measuring devices, etc.).

The image sensor 1000 may include a control unit including a pixel array 1110, a controller 1130, a row driver 1120, and a pixel signal processor 1140.

As shown in FIG. 2, the pixel array 1110 may include a plurality of pixels two-dimensionally arranged along a first direction DR1 and a second direction DR2. The plurality of pixels may be arranged in a regular pattern to generate a high-quality image. For example, the plurality of pixels may be arranged in a Bayer pattern or a chess mosaic pattern. When the plurality of pixels have a Bayer pattern, the pixels in the pixel array 1110 may receive red light, green light, and blue light, respectively. In example embodiments, the plurality of pixels may receive cyan light, magenta light, yellow light, and white (W) light. Each of the pixels may include a photoelectric conversion device. The photoelectric conversion device may absorb light to generate charge carriers (electrons or holes). For example, the photoelectric conversion device may include photodiodes, phototransistors, photogates, pinned photodiodes, or a combination thereof. Output voltages of the plurality of pixels may be determined based on the generated charge carriers.

The pixel array 1110 may include a pixel group PXG. The pixel group PXG may be a set of pixels PX sharing a reset transistor RX, a selection transistor SX, and a source follower transistor DX. Although the pixel group PXG is illustrated as being composed of four pixels PX, in example embodiments the pixel group PXG may include less than or more than four pixels PX.

The pixel array 1110 may be driven by receiving a plurality of driving signals, such as a row selection signal, a reset signal, and a charge transfer signal, from the row driver 1120. The row driver 1120 may provide a plurality of driving signals to the pixel array 1110 for driving the plurality of pixels. In example embodiments, the driving signals may be provided for each row of the pixel array 1110. Pixels belonging to one row of the pixel array 1110 selected by the driving signals of the row driver 1120 may be simultaneously activated by a signal output from the row driver 1120. The pixels belonging to the selected row may provide output voltages according to absorbed light to output lines of corresponding columns. In example embodiments, the pixels belonging to the selected one row may provide the output voltages together. The output voltages may be provided to correlated double sampler 1142.

The pixel signal processor 1140 may include a correlated double sampler (CDS) 1142, an analog-to-digital converter (ADC) 1144, and a buffer 1146. The correlated double sampler 1142 may sample and hold the output voltages provided by the pixel array 1110. The correlated double sampler 1142 can reduce noise and improve Signal Noise Ratio (SNR). The correlated double sampler 1142 can be configured to remove noise voltages from the output voltages of the pixel. For example, the correlated double sampler 1142 may double sample a specific noise level and a signal level by an output signal, and output a difference level corresponding to a difference between the noise level and the signal level. The correlated double sampler 1142 may output a result based on ramp signals generated by a ramp signal generator 1148.

The analog-to-digital converter 1144 may convert an analog signal corresponding to the difference level received from the correlated double sampler 1142 into a digital signal. The buffer 1146 may latch digital signals, and the latched signals may be sequentially output to the outside of the image sensor 1000 and transferred to an image processor (not shown).

The controller 1130 may control the row driver 1120 so that the pixel array 1110 absorbs light to accumulate charge carriers, temporarily stores the accumulated charge, and ouputs an electrical signal according to the accumulated charge to the outside of the pixel array 1110. Also, the controller 1130 may control the pixel signal processor 1140 to measure an output voltage provided by the pixel array 1110.

Referring to FIG. 3, each of the plurality of pixels PX may include a photoelectric conversion device PD, a transfer transistor TX, and a floating diffusion region FD. The photoelectric conversion device PD may generate and accumulate photocharges in proportion to the amount of light incident from the outside, and may include a photodiode, a phototransistor, a photogate, a pinned photodiode, or a combination thereof.

The transfer transistor TX may include a transfer gate TG. The transfer gate TG may transfer charge carriers generated by the photoelectric conversion device PD to the floating diffusion region FD. A transfer control voltage provided from the row driver 1120 may be applied to the transfer gate TG. For example, a channel may be formed between the photoelectric conversion device PD and the floating diffusion region FD by the transfer control voltage applied to the transfer gate TG. Charge carriers generated by the photoelectric conversion device PD may move to the floating diffusion region FD along the channel between the photoelectric conversion device PD and the floating diffusion region FD. A drain terminal of the transfer transistor TX may be electrically connected to the floating diffusion region FD, and a source terminal of the transfer transistor TX may be electrically connected to the photoelectric conversion device PD.

The floating diffusion region FD may receive, accumulate, and store charges generated by the photoelectric conversion device PD. The source follower transistor DX may be controlled according to the amount of charge accumulated in the floating diffusion region FD. A gate terminal of the source follower transistor DX may be electrically connected to the floating diffusion region FD. A second power voltage VDD2 may be applied to a drain terminal of the source follower transistor DX. A source terminal of the source follower transistor DX may be electrically connected to a drain terminal of the selection transistor SX. The source follower transistor DX may be a source follower buffer amplifier that outputs a current proportional to the amount of charge accumulated in the floating diffusion region FD.

The reset transistor RX may periodically reset charges accumulated in the floating diffusion region FD. A gate terminal of the reset transistor RX may be electrically connected to a reset signal line RG. A drain terminal of the reset transistor RX may be connected to the floating diffusion region FD. A first power voltage VDD1 may be applied to a source terminal of the reset transistor RX. In example embodiments, the first power voltage VDD1 may be substantially equal to the second power voltage VDD2. When the reset transistor RX is turned on, the first power voltage VDD1 applied to the source terminal of the reset transistor RX is transferred to the floating diffusion region FD. When the reset transistor RX is turned on, charges accumulated in the floating diffusion region FD are discharged to reset the floating diffusion region FD. When electrons are charge carriers, the voltage of the floating diffusion region FD may decrease as electrons are accumulated in the floating diffusion region FD. When the reset transistor RX is turned on, electrons of the floating diffusion region FD are discharged to the outside, and the voltage of the floating diffusion region FD may increase to the first power voltage VDD1. As the first power voltage VDD1 is applied to the floating diffusion region FD, the first power voltage VDD1 may be applied to the gate terminal of the source follower transistor DX to reset the output of the source follower transistor DX.

The selection transistor SX may select a plurality of pixels PX in each row. The selection transistor SX may transfer current generated by the source follower transistor DX included in each of the selected pixels to an output line (not shown). A drain terminal, a source terminal, and a gate terminal of the selection transistor SX may be electrically connected to the source terminal, the output line, and the row selection line SG of the source follower transistor DX, respectively. A selection control signal applied from the row selection line SG may be applied to the gate terminal of the selection transistor SX to output a signal generated by the source follower transistor DX to the output line.

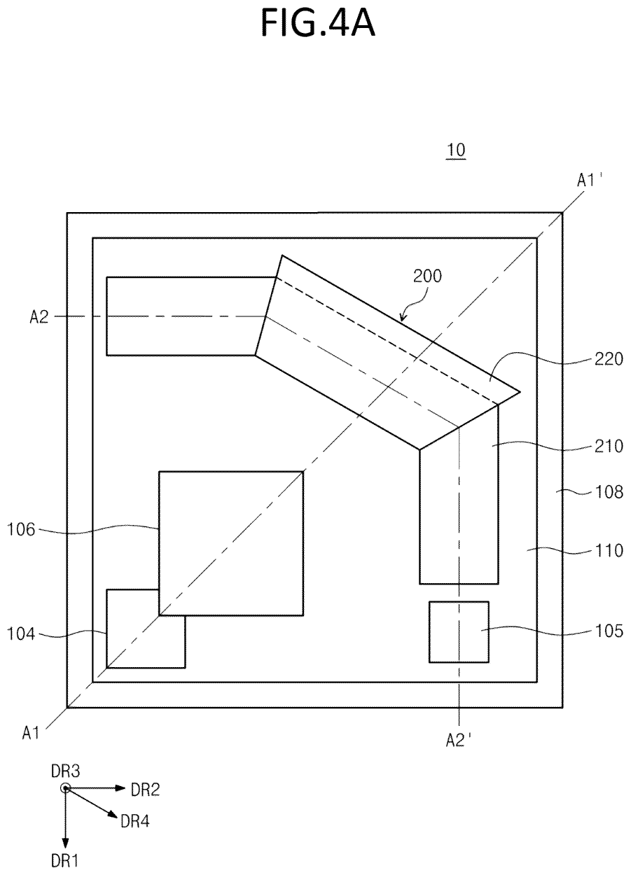

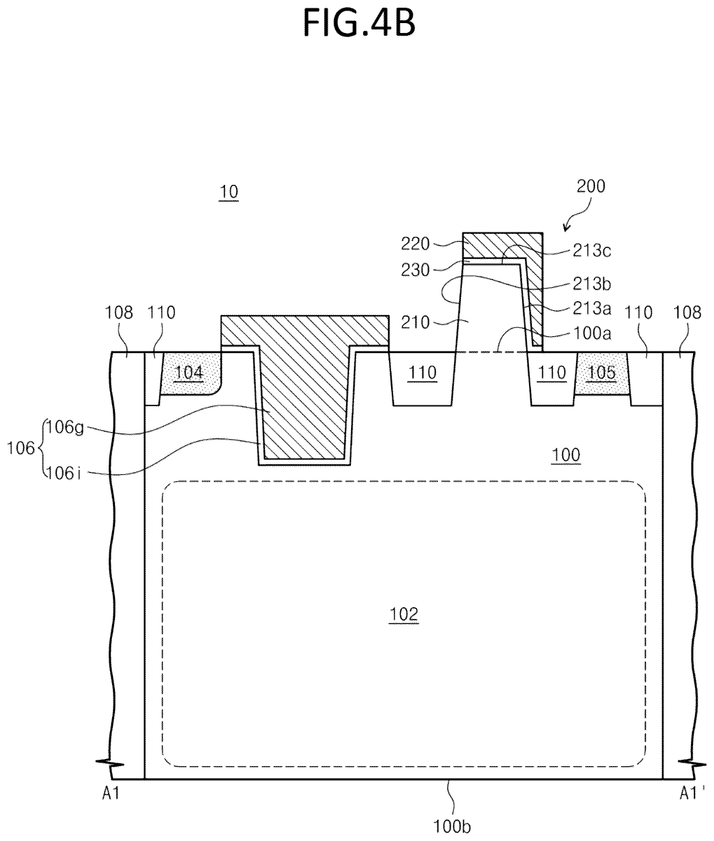

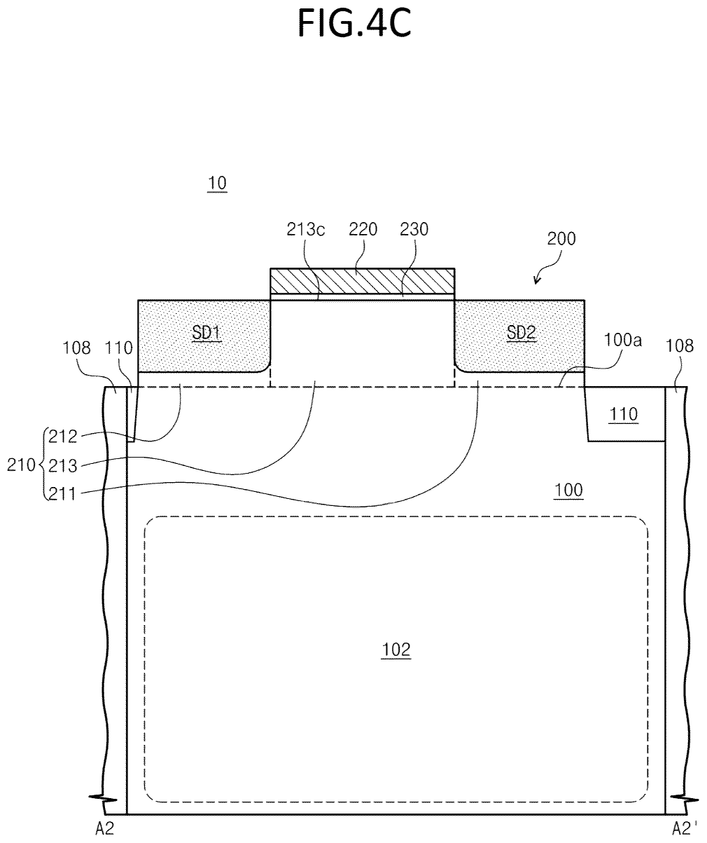

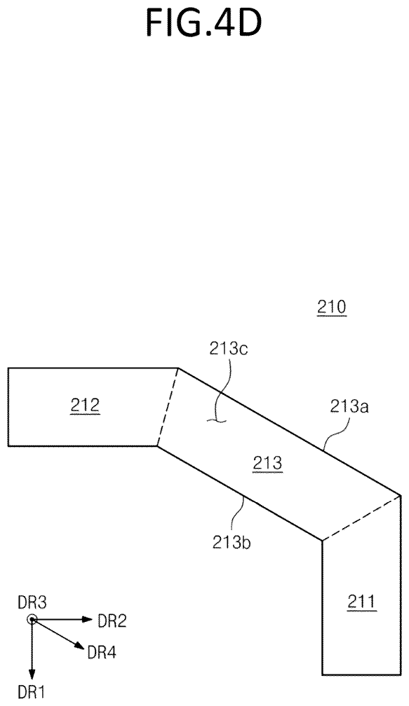

FIG. 4A is a plan view illustrating a pixel of an image sensor according to example embodiments. FIG. 4B is a cross-sectional view taken along the line A1-A1′ of FIG. 4A. FIG. 4C is a cross-sectional view taken along the line A2-A2′ of FIG. 4A. FIG. 4D is a plan view illustrating the semiconductor pattern of FIG. 4A.

Referring to FIGS. 4A to 4C, a substrate 100 may be provided. The substrate 100 may be a semiconductor substrate. In example embodiments hereinafter, the substrate 100 is described as a silicon (Si) substrate. However, the technical spirit of the present inventive concepts may be applied to other semiconductor substrates. The substrate 100 may include a first surface 100a and a second surface 100b facing in opposite directions. The first surface 100a and the second surface 100b may extend along the first and second directions DR1 and DR2. The first direction DR1 and the second direction DR2 may correspond to a first axis direction and a second axis direction of a cubic structure, respectively. The first surface 100a and the second surface 100b may be spaced apart from each other along the third direction DR3. The third direction DR3 may be perpendicular to the first and second directions DR1 and DR2. The third direction DR3 may be a third axis direction of the cubic structure. When the crystal axes of the cubic structure are indicated by the x-axis, y-axis, and z-axis, the first direction DR1, the second direction DR2, and the third direction DR3 may be the x-axis direction, the y-axis direction, and the z-axis direction, respectively. When the crystal axes of the cubic structure are indicated as a1-axis, a2-axis, and a3-axis, the first direction DR1, the second direction DR2, and the third direction DR3 may be the a1-axis direction, the a2-axis direction, and a3 direction, respectively. The substrate 100 may be a substrate. The equivalent plane index of the first surface 100a may be {100}. Hereinafter, equivalent plane indices may represent Miller indices of crystallographically equivalent planes. For example, the first surface 100a may be a (100) plane.

The substrate 100 may have a first conductivity type. For example, the first conductivity type may be p-type or n-type. When the conductivity type of the substrate 100 is p-type, the substrate 100 may be a silicon (Si) substrate containing group 3 elements (e.g., boron (B), aluminum (Al), gallium (Ga), indium (In), etc.) or group 2 elements as impurities. When the conductivity type of the substrate 100 is n-type, the substrate 100 may be a silicon (Si) substrate containing group 5 elements (e.g., phosphorus (P), arsenic (As), antimony (Sb), etc.), or group 6 or group 7 elements as impurities. Hereinafter, a region having a p-type conductivity may include group 2 or 3 elements as impurities. Hereinafter, a region having an n-type conductivity may include group 5, 6, or 7 elements as impurities. Hereinafter, impurities that enable the substrate 100 to have the first conductivity type and the second conductivity type may be referred to as first impurities and second impurities, respectively. When the first conductivity type is p-type or n-type, the second conductivity type may be n-type or p-type, respectively. The substrate 100 may be an epi layer formed by an epitaxial growth process. For brevity of description, the first conductivity type is described as p-type and the second conductivity type is described as n-type in the following.

A device isolation layer 110 may be provided on the substrate 100. The device isolation layer 110 may define an active region. The active region may be a region in which a transfer gate structure 106, a floating diffusion region 104, and a ground region 105 are provided. The first surface 100a may refer to a top surface of the active region. In a plan view, the device isolation layer 110 may surround the active region. The device isolation layer 110 may have a thickness along the third direction DR3. The thickness of the device isolation layer 110 may be smaller than the thickness of a pixel isolation layer 108 described below. For example, the device isolation layer 110 may be a shallow trench isolation (STI) layer. In example embodiments, the top surface of the device isolation layer 110 may be positioned at substantially the same level as the first surface 100a. The device isolation layer 110 may include silicon nitride, silicon oxide, silicon oxynitride, or a combination thereof.

The pixel isolation layer 108 may be provided on a side surface of the substrate 100. In a plan view, the pixel isolation layer 108 may surround the substrate 100. The pixel isolation layer 108 may extend along the third direction DR3. In example embodiments, the top and bottom surfaces of the pixel isolation layer 108 may be positioned at substantially the same level as the first and second surfaces 100a and 100b, respectively. The pixel isolation layer 108 may limit, prevent or reduce an electric crosstalk phenomenon that lowers a signal-to-noise ratio due to exchange of charge carriers between adjacent pixels. For example, the pixel isolation layer 108 may include a conductive material (e.g., at least one of doped polysilicon, metal, metal silicide, metal nitride, or a metal-containing material), an insulating material (e.g., a silicon-based insulating material (e.g., silicon nitride, silicon oxide, and/or silicon oxynitride), or a high dielectric material (e.g., a metal oxide including at least one metal selected from a group consisting of hafnium (Hf), zirconium (Zr), aluminum (Al), tantalum (Ta), titanium (Ti)), yttrium (Y), and lanthanoid (La)). In example embodiments, the sidewall of the pixel isolation layer 108 may be doped with a material having relatively high reflectivity to limit, prevent or reduce optical crosstalk in which the light is detected in a pixel adjacent to the pixel where the light is incident. For example, a material with high reflectivity may be boron. When the pixel isolation layer 108 includes a conductive material, in example embodiments, a negative fixed charge layer may be provided between the pixel isolation layer 108 and the substrate 100. The negative fixed charge layer may include a metal oxide containing at least one metal selected from a group consisting of hafnium (Hf), zirconium (Zr), aluminum (Al), tantalum (Ta), titanium (Ti), yttrium (Y), and lanthanoids (La). However, the structure of the pixel isolation layer 108 may be determined as desired. In example embodiments, the pixel isolation layer 108 may be an insulating layer having a single structure. In example embodiments, the pixel isolation layer 108 may include an upper insulating layer positioned adjacent to the first surface 100a and a lower insulating layer positioned adjacent to the second surface 100b.

A photoelectric conversion region 102 may be provided in the substrate 100. In example embodiments, the photoelectric conversion region 102 may include at least one photodiode. For example, the photoelectric conversion region 102 may include a pn photodiode. For example, the p-type region of the photoelectric conversion region 102 may be the substrate 100, and the n-type region may be formed by implanting second impurities into the substrate 100. In example embodiments, the p-type region may be formed by implanting first impurities into the substrate 100. For example, the doping concentration of the p-type region may be relatively higher than that of the substrate 100. In example embodiments, first impurities may be further implanted into the substrate 100 to form a plurality of pn junctions positioned at different depths. However, in example embodiments the photoelectric conversion region 102 may include a photodiode. In example embodiments, the photoelectric conversion region 102 may include phototransistors, photogates, or pinned photodiodes. When light is incident on the photoelectric conversion region 102, an electron-hole pair (EHP) may be generated in the photoelectric conversion region 102. For example, electron-hole pairs may be generated in a depletion region formed in a region adjacent to the pn junction. Since light penetrates the substrate 100 at different depths depending on the wavelength, when a plurality of pn junctions positioned at different depths are used, light having different wavelengths can be efficiently detected. As the intensity of light incident on the photoelectric conversion region 102 increases, more electron-hole pairs may be generated. When a reverse bias is applied to the photoelectric conversion region 102, charge carriers (electrons or holes) may be accumulated in the photoelectric conversion region 102. Charge carriers accumulated in the photoelectric conversion region 102 may move to the floating diffusion region 104 by a voltage applied to the transfer gate electrode 106g. The photoelectric conversion region 102 may be spaced apart from the floating diffusion region 104.

A floating diffusion region 104 may be provided on an upper portion of the substrate 100. The floating diffusion region 104 may have the second conductivity type. In example embodiments, the floating diffusion region 104 may be formed by implanting the second impurities into the substrate 100. The floating diffusion region 104 may be spaced apart from the photoelectric conversion region 102. A region between the floating diffusion region 104 and the photoelectric conversion region 102 (e.g., one region of the substrate 100) may have the first conductivity type. The floating diffusion region 104 may receive and accumulate charge carriers provided from the photoelectric conversion region 102.

A transfer gate structure 106 may be provided adjacent to the floating diffusion region 104 and the photoelectric conversion region 102. The transfer gate structure 106 may be inserted into the substrate 100. In example embodiments, one portion of the transfer gate structure 106 may protrude onto the first surface 100a and another portion may be inserted into the substrate 100. The transfer gate structure 106 may extend along the third direction DR3. The transfer gate structure 106 may be referred to as a Vertical Transfer Gate (VTG). The transfer gate structure 106 may include a transfer gate electrode 106g and a transfer gate insulating layer 106i.

The transfer gate electrode 106g may be spaced apart from the substrate 100. The transfer gate electrode 106g may extend along the third direction DR3. The transfer gate electrode 106g may include an electrically conductive material. For example, the transfer gate electrode 106g may include doped polysilicon or a metal (e.g., copper (Cu), aluminum (Al), molybdenum (Mo), platinum (Pt), titanium (Ti), tantalum (Ta), tungsten (W), or combinations thereof).

The transfer gate insulating layer 106i may be provided between the transfer gate electrode 106g and the substrate 100. The transfer gate insulating layer 106i may extend along the surface of the transfer gate electrode 106g. The transfer gate insulating layer 106i may be configured to electrically separate the transfer gate electrode 106g and the substrate 100. For example, the transmission gate insulating layer 106i may include a silicon-based insulating material (e.g., silicon nitride, silicon oxide, and/or silicon oxynitride) or a high dielectric material (e.g., a metal oxide including at least one metal selected from a group consisting of hafnium (Hf), zirconium (Zr), aluminum (Al), tantalum (Ta), titanium (Ti)), yttrium (Y), and lanthanoid (La)).

The transfer gate structure 106, the photoelectric conversion region 102, and the floating diffusion region 104 may constitute a transfer transistor. The transfer gate structure 106, the photoelectric conversion region 102, and the floating diffusion region 104 may constitute the gate, source, and drain of the transfer transistor, respectively. When a voltage is applied to the transfer gate electrode 106g, a channel of the second conductivity type may be formed in a region adjacent to the transfer gate structure 106 of the substrate 100. The channel may be configured to move charge carriers generated in the photoelectric conversion region 102 to the floating diffusion region 104. When no voltage is applied to the transfer gate electrode 106g, charge carriers generated in the photoelectric conversion region 102 may be accumulated in the photoelectric conversion region 102.

The ground region 105 may be provided on an upper portion of the substrate 100. The ground region 105 may have the second conductivity type. The ground region 105 may be formed by implanting second impurities into the substrate 100. The ground region 105 may be spaced apart from the photoelectric conversion region 102. Ground region 105 may be configured to apply a ground voltage to substrate 100.

A pixel transistor 200 may be provided on the first surface 100a of the substrate 100. The pixel transistor 200 may be any one of transistors used in a circuit necessary for driving the image sensor. For example, the pixel transistor 200 may be any one of a source follower transistor, a reset transistor, and a selection transistor. The pixel transistor 200 may include a semiconductor pattern 210, a gate electrode 220, and a gate insulating layer 230.

The semiconductor pattern 210 may be provided on the substrate 100. The semiconductor pattern 210 may include substantially the same material as the substrate 100. For example, the semiconductor pattern 210 may be a silicon (Si) pattern. The semiconductor pattern 210 may be connected to the substrate 100 without a boundary. In example embodiments, the semiconductor pattern 210 may be formed by an epitaxial growth process using the substrate 100 as a seed layer. In example embodiments, the semiconductor pattern 210 may be formed by etching an upper portion of the substrate 100. The semiconductor pattern 210 may include a first sub pattern 211, a second sub pattern 212, and a third sub pattern 213 extending in different directions. The first sub pattern 211 may extend along the first direction DR1. The second sub pattern 212 may be spaced apart from the first sub pattern 211. The second sub pattern 212 may extend along the second direction DR2. The third sub pattern 213 may be provided between the first sub pattern 211 and the second sub pattern 212. The third sub pattern 213 may extend along a fourth direction DR4 crossing the first and second directions DR1 and DR2. In a plan view, the semiconductor pattern 210 may have a shape bent twice.

The semiconductor pattern 210 may include a first source/drain region SD1 and a second source/drain region SD2. The first source/drain region SD1 may be provided at the second sub pattern 212. The first source/drain region SD1 may have the second conductivity type. Although the first source/drain region SD1 is illustrated as being provided at a part of the second sub pattern 212, in example embodiments the first source/drain region SD1 may be provided at the entire second sub pattern 212. When one region of the second sub pattern 212 is the first source/drain region SD1, the remaining region of the second sub pattern 212 may have the first conductivity type.

The second source/drain region SD2 may be provided at the first sub pattern 211. The second source/drain region SD2 may have the second conductivity type. Although the second source/drain region SD2 is illustrated as being provided at a part of the first sub pattern 211, in example embodiments the second source/drain region SD2 may be provided at the entire first sub pattern 211. When one region of the first sub pattern 211is the second source/drain region SD2, the remaining region of the first sub pattern 211 may have the first conductivity type.

The third sub pattern 213 may have the first conductivity type. A channel connecting the first source/drain region SD1 and the second source/drain region SD2 may be formed in the third sub pattern 213 by a voltage applied to the gate electrode 220. The channel may be provided adjacent to a surface of the third sub pattern 213. The third sub pattern 213 may have an A1 surface 213a, an A2 surface 213b, and an A3 surface 213c. The A1 side 213a and the A2 side 213b may be both side surfaces of the third sub pattern 213 positioned opposite to each other. The A1 surface 213a, the A2 surface 213b, and the A3 surface 213c may extend along the fourth direction DR4. The A3 surface 213c may be a top surface of the third sub pattern 213. The A3 surface 213c may have substantially the same plane index as the first surface 100a. For example, the A3 surface 213c may be a (100) plane. The plane index of the A1 surface 213a may be determined to have a relatively low density of interface traps.

In example embodiments, the A1 surface 213a may be a {310} plane. Hereinafter, the {310} plane may refer not only to the {310} plane, but also to a substantial {310} plane. The substantial {310} plane may be, for example, a plane that is distorted at a fine angle from the {310} plane and has substantially the same characteristics as the {310} plane. For example, the A1 surface 213a may be a (310) plane. When the A1 surface 213a is the (310) plane, the ratio between the magnitude of the first direction DR1 component and the second direction DR2 component of the fourth direction DR4 may be 1:3. For example, the A1 surface 213a may be a (130) plane. When the A1 surface 213a is the (130) plane, the ratio between the magnitude of the first direction DR1 component and the second direction DR2 component of the fourth direction DR4 may be 3:1. In example embodiments, the A1 surface 213a may be a {210} plane. Hereinafter, the {210} plane may refer to a substantial {210} plane as well as the {210} plane. The substantial {210} plane may be, for example, a plane that is distorted at a fine angle from the {210} plane and has substantially the same characteristics as the {210} plane. For example, the A1 surface 213a may be a (210) plane. When the A1 surface 213a is the (210) plane, the ratio between the magnitude of the first direction DR1 component and the second direction DR2 component of the fourth direction DR4 may be 1:2. For example, the A1 surface 213a may be a (120) plane. When the A1 surface 213a is the (120) plane, the ratio between the magnitude of the first direction DR1 component and the second direction DR2 component of the fourth direction DR4 may be 2:1.

The gate electrode 220 may be provided on the third sub pattern 213. The gate electrode 220 may be provided on the A3 surface 213c and the A1 surface 213a. In a plan view, the gate electrode 220 may completely overlap the A3 surface 213c and the A1 surface 213a. The gate electrode 220 may include an electrically conductive material. For example, the gate electrode 220 may include doped polysilicon or a metal (e.g., copper (Cu), aluminum (Al), molybdenum (Mo), platinum (Pt), titanium (Ti), tantalum (Ta), tungsten (W), or a combination thereof). When the pixel transistor 200 is the source follower transistor, the gate electrode 220 may be electrically connected to the floating diffusion region 104. A voltage generated by the amount of charge accumulated in the floating diffusion region 104 may be a gate voltage. When the pixel transistor 200 includes the reset transistor, a reset signal voltage may be applied to the gate electrode 220 to apply an initial voltage to the floating diffusion region 104. Applying the initial voltage to the floating diffusion region 104 may be referred to as a reset operation. When the pixel transistor 200 includes the selection transistor, a selection signal voltage may be applied to the gate electrode 220 to output a signal.

The gate insulating layer 230 may be provided between the gate electrode 220 and the third sub pattern 213. The gate insulating layer 230 may include an electrical insulating material. For example, the gate insulating layer 230 may include silicon oxide, silicon nitride, or silicon oxynitride. In example embodiments, the gate insulating layer 230 may further extend over the device isolation layer 110, the transfer gate structure 106, the floating diffusion region 104, and the ground region 105.

As the gate electrode 220 is provided on the A3 surface 213c and the A1 surface 213a, a channel of the pixel transistor 200 may be formed on the A3 surface 213c and the A1 surface 213a. Formation of a channel on a surface may refer to formation of the channel on the surface and a region adjacent to the surface. Due to the material properties of the semiconductor pattern 210 and the gate insulating layer 230, charge trap phenomena may occur at the interface between the semiconductor pattern 210 and the gate insulating layer 230. Charge trap phenomena are factors that generate noise of an image sensor, such as random noises and random telegraph signals. For the {100} plane, the {110} plane, the {310} plane, and the {210} plane of a silicon layer, the interfacial trap densities of a silicon (Si) layer and a silicon dioxide (SiO2) layer are about 4.0, 4.1, 2.4, and 2.0. When the channel is formed on the {310} plane (e.g., (310) plane) or the {210} plane (e.g., (210) plane), the charge trap phenomena can be reduced and thus improved compared to the case where the channel is formed on the {100} plane or the {110} plane.

According to example embodiments of the inventive concepts, the pixel 10 having improved trap characteristics can be provided by using a surface having a low interfacial trap density (e.g., a {310} plane or a {210} plane) as a channel. Accordingly, an image sensor with improved noise characteristics may be provided.

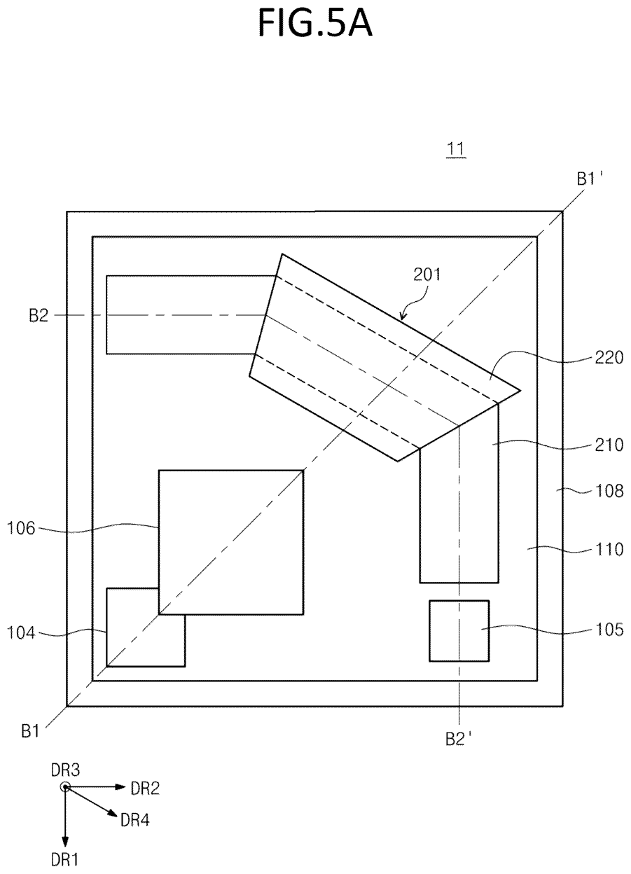

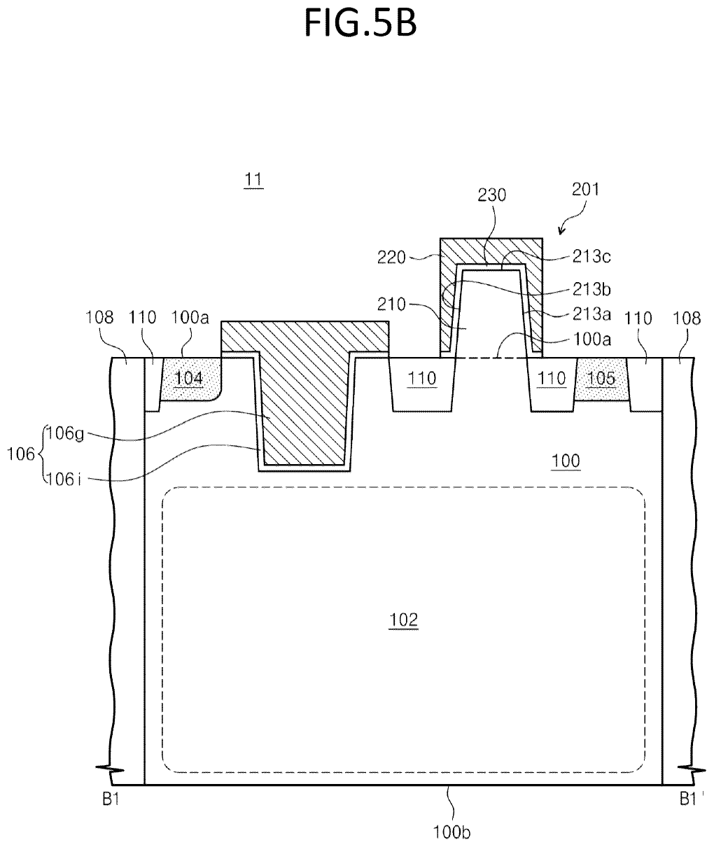

FIG. 5A is a plan view illustrating a pixel of an image sensor according to example embodiments. FIG. 5B is a cross-sectional view taken along line B1-B1′ of FIG. 5A. A cross-sectional view along line B2-B2′ of FIG. 5A may be substantially the same as that of FIG. 4C. For brevity of description, differences from the embodiment described with reference to FIG. 4A are described.

Referring to FIGS. 4C, 5A, and 5B, unlike the description with reference to FIG. 4A, the gate electrode 220 and the gate insulating layer 230 may further extend over the A2 surface 213b of the third sub pattern 213. The equivalent plane index of the A2 surface 213b may be determined to have a low interfacial trap density. In example embodiments, the A2 surface 213b may be a {310} plane. For example, the A2 surface 213b may be a (3̅1̅0) plane or a (1̅3̅0) plane. In example embodiments, the A2 surface 213b may be a {210} plane. For example, the A2 surface 213b may be a (2̅1̅0) plane or a (1̅2̅0) plane. In example embodiments, the A1 surface 213a and A2 surface 213b may extend substantially parallel.

The channel of the pixel transistor 200 may be formed on the A1 surface 213a, the A2 surface 213b, and the A3 surface 213c as the gate electrode 220 is provided on the A1 surface 213a, the A2 surface 213b, and the A3 surface 213c. Since the channel is formed on the {310} plane (e.g., (310) plane and (3̅1̅0) plane) or the {210} plane (e.g., (210) plane and (2̅1̅0) plane), the charge trap phenomena can be improved.

According to the example embodiments of the inventive concepts, the pixel 11 having an improved charge trap phenomena by using a surface having a low interfacial trap density (e.g., a {310} plane or a {210} plane) as a channel may be provided. Accordingly, the image sensor with improved noise characteristics may be provided.

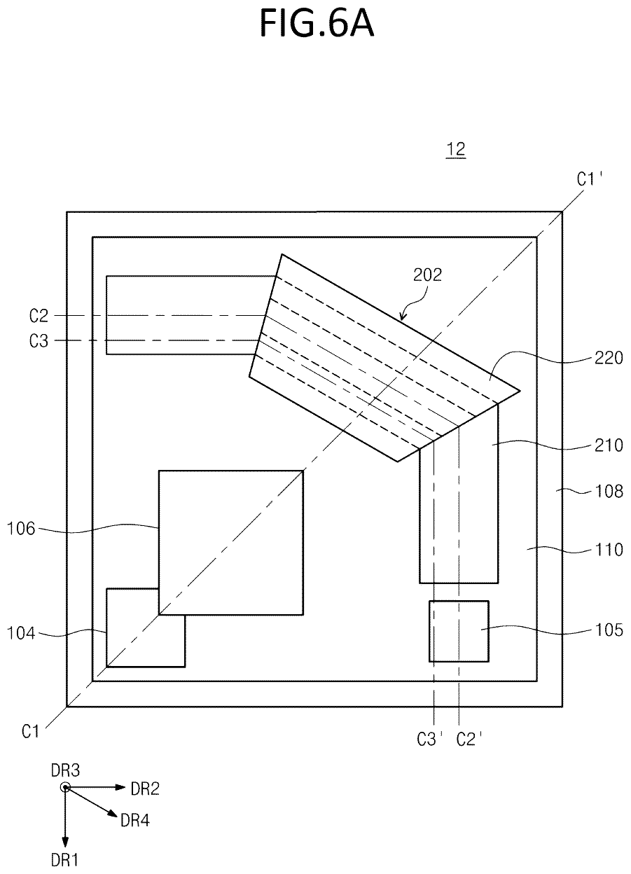

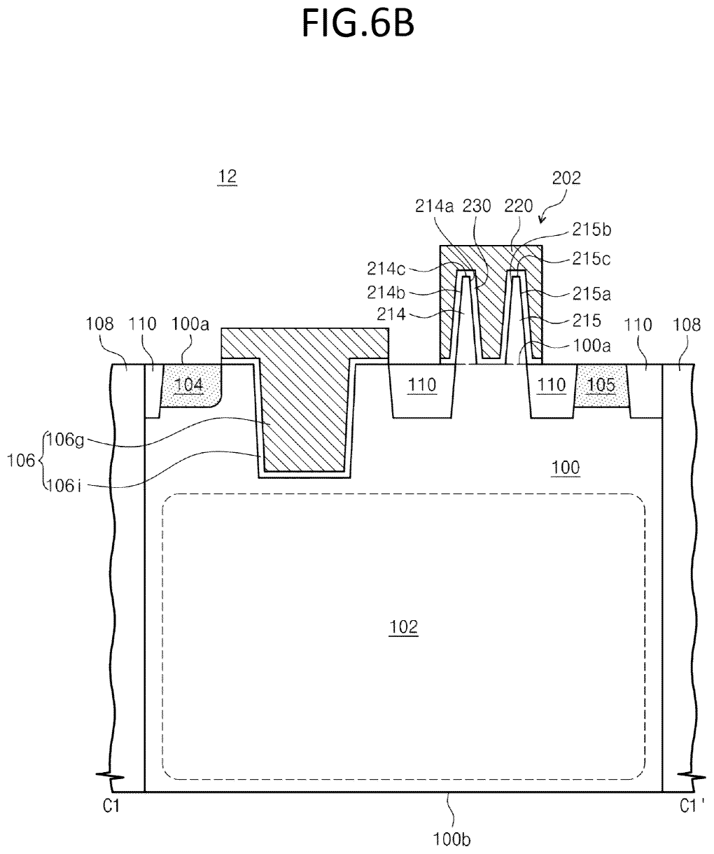

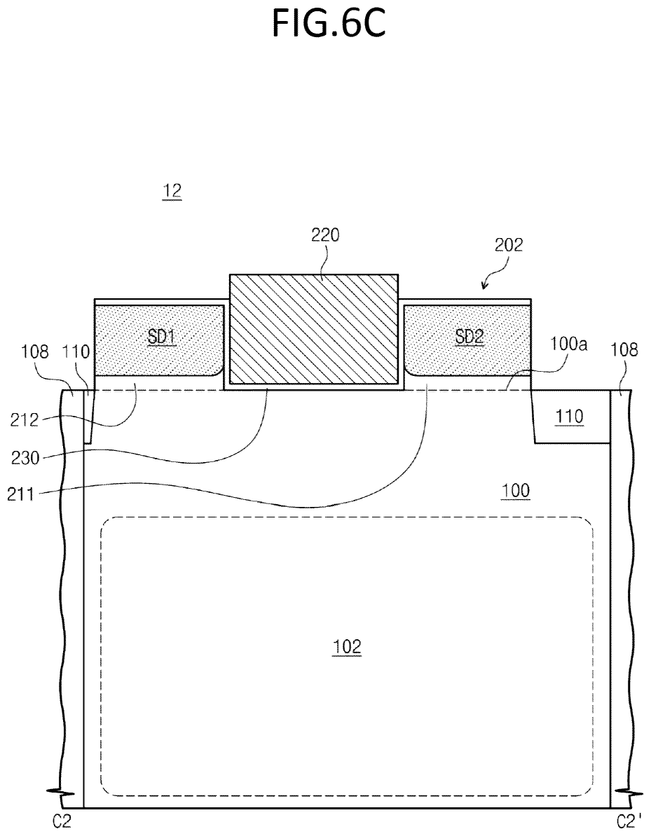

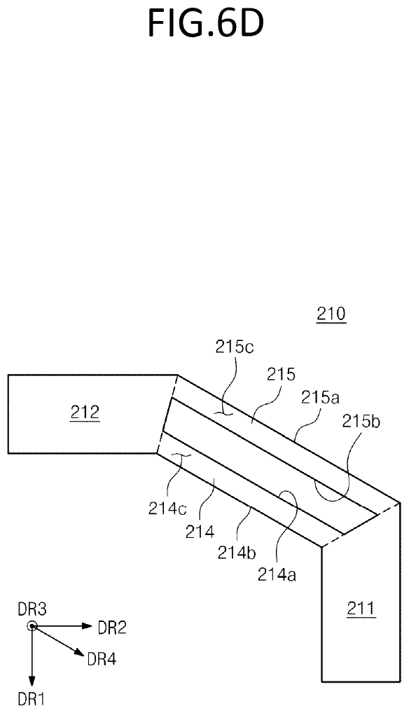

FIG. 6A is a plan view illustrating a pixel of an image sensor according to example embodiments. FIG. 6B is a cross-sectional view taken along line C1-C1′ of FIG. 6A. FIG. 6C is a cross-sectional view taken along line C2-C2′ of FIG. 6A. A cross-sectional view along line C3-C3′ of FIG. 6A may be substantially the same as that of FIG. 4C. FIG. 6D is a plan view illustrating the semiconductor pattern of FIG. 6A. For brevity of description, differences from the embodiment described with reference to FIG. 4A are described.

Referring to FIGS. 4C and 6A to 6D, unlike the description with reference to FIG. 4A, the semiconductor pattern 210 may include a fourth sub pattern 214 and a fifth sub pattern 215 instead of the third sub pattern 213. The fourth sub pattern 214 and the fifth sub pattern 215 may extend along the fourth direction DR4 between the first sub pattern 211 and the second sub pattern 212. The fourth sub pattern 214 and the fifth sub pattern 215 may be spaced apart from each other.

The fourth sub pattern 214 and the fifth sub pattern 215 may have the first conductivity type. A channel connecting the first source/drain region SD1 and the second source/drain region SD2 may be formed in the fourth sub pattern 214 and the fifth sub pattern 215 by a voltage applied to the gate electrode 220. The channel may be provided adjacent to surfaces of the fourth sub pattern 214 and the fifth sub pattern 215. The fourth sub pattern 214 may have a B1 surface 214a, a B2 surface 214b, and a B3 surface 214c. The B1 surface 214a, the B2 surface 214b, and the B3 surface 214c may extend along the fourth direction DR4. The B1 surface 214a and the B2 surface 214b may be both side surfaces of the fourth sub pattern 214 positioned opposite to each other. The B3 surface 214c may be a top surface of the fourth sub pattern 214. The fifth sub pattern 215 may have a C1 surface 215a, a C2 surface 215b, and a C3 surface 215c. The C1 surface 215a, C2 surface 215b, and C3 surface 215c may extend along the fourth direction DR4. The C1 surface 215a and the C2 surface 215b may be both side surfaces of the fifth sub pattern 215 positioned opposite to each other. The C3 surface 215c may be a top surface of the fifth sub pattern 215. The B1 surface 214a and the C2 surface 215b may face each other.

The B3 surface 214c and the C3 surface 215c may have substantially the same plane index as the first surface 100a. For example, the B3 surface 214c and the C3 surface 215c may be (100) planes. The plane indices of the B1 surface 214a, the B2 surface 214b, the C1 surface 215a, and the C2 surface 215b may be determined to have a low interfacial trap density. In example embodiments, each of the B1 surface 214a, the B2 surface 214b, the C1 surface 215a, and the C2 surface 215b may be at least one of a {310} plane and a {210} plane. For example, the B1 surface 214a and the C1 surface 215a may be a (310) plane, and the C2 surface 215b and the B2 surface 214b may be a (3̅1̅0) plane. For example, the B1 surface 214a and the C1 surface 215a may be a (210) surface, and the C2 surface 215b and the B2 surface 214b may be a (2̅1̅0) surface.

The gate electrode 220 may be provided on the fourth sub pattern 214 and the fifth sub pattern 215. The gate electrode 220 may be configured to face the B1 surface 214a, the B2 surface 214b, the B3 surface 214c, the C1 surface 215a, the C2 surface 215b, and the C3 surface 215c. A portion of the gate electrode 220 may extend to a region between the fourth sub pattern 214 and the fifth sub pattern 215.

The gate insulating layer 230 may be provided between the gate electrode 220 and the semiconductor pattern 210. For example, the gate insulating layer 230 may cover the B1 surface 214a, the B2 surface 214b, the B3 surface 214c, the C1 surface 215a, the C2 surface 215b, and the C3 surface 215c. The gate insulating layer 230 may electrically separate the semiconductor pattern 210 and the gate electrode 220. In example embodiments, the gate insulating layer 230 and the gate electrode 220 may fill a region between the fourth sub pattern 214 and the fifth sub pattern 215.

According to example embodiments of the inventive concepts, the pixel 12 in which the charge trap phenomena is improved by increasing an area of a surface having a low interfacial trap density (e.g., {310} plane, {210} plane) on which a channel is formed using the fourth sub pattern 214 and the fifth sub pattern 215 may be provided. Accordingly, the image sensor with improved noise characteristics may be provided.

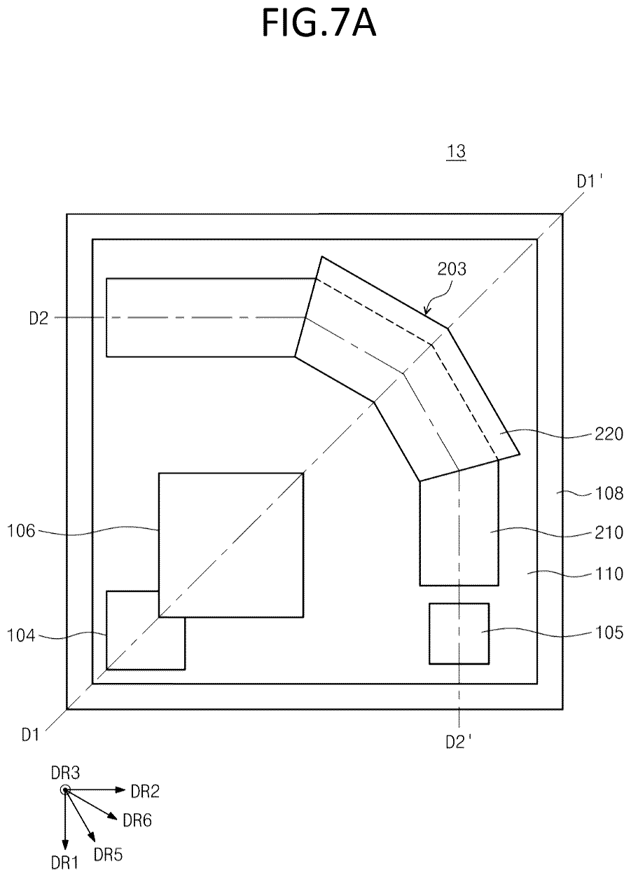

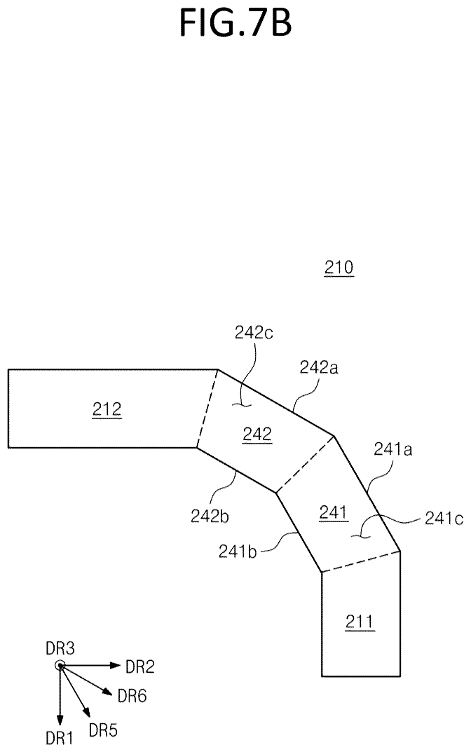

FIG. 7A is a plan view illustrating pixel of an image sensor according to example embodiments. FIG. 7B is a plan view illustrating the semiconductor pattern of FIG. 7A. A cross-sectional view taken along the line D1-D1′ of FIG. 7A may be substantially the same as that of FIG. 4B. A cross-sectional view taken along the line D2-D2′ of FIG. 7A may be substantially the same as that of FIG. 4C. For brevity of description, differences from the embodiment described with reference to FIG. 4A are described.

Referring to FIGS. 4B, 4C, 7A, and 7B, unlike the description with reference to FIG. 4A, the semiconductor pattern 210 may include a sixth sub pattern 241 and a seventh sub pattern 242 instead of the third sub pattern 213. The sixth sub pattern 241 may be provided between the seventh sub pattern 242 and the first sub pattern 211. One end portion of the sixth sub pattern 241 may be connected to the first sub pattern 211 and the other end portion may be connected to the seventh sub pattern 242. The sixth sub pattern 241 may extend along a fifth direction DR5 crossing the first and second directions DR1 and DR2. The fifth direction DR5 may have a first direction DR1 component and a second direction DR2 component. In example embodiments, the ratio of the magnitude of the component in the first direction DR1 of the fifth direction DR5 to the magnitude of the component in the second direction DR2 of the fifth direction DR5 may be 3:1, 2:1, or 1:2.

The sixth sub pattern 241 may have the first conductivity type. A channel connecting the first source/drain region SD1 and the second source/drain region SD2 may be formed in the sixth sub pattern 241 by a voltage applied to the gate electrode 220. The channel may be provided adjacent to the surface of the sixth sub pattern 241. The sixth sub pattern 241 may have a D1 surface 241a, a D2 surface 241b, and a D3 surface 241c. The D1 surface 241a, the D2 surface 241b, and the D3 surface 241c may extend along the fifth direction DR5. The D1 surface 241a and the D2 surface 241b may be both side surfaces of the sixth sub pattern 241 positioned opposite to each other. The D3 surface 241c may be a top surface of the sixth sub pattern 241. The D3 surface 241c may have substantially the same plane index as the first surface 100a. For example, the D3 surface 241c may be a (100) plane. The equivalent plane index of the D1 surface 241a may be determined to have a low interfacial trap density. For example, the D1 surface 241a may be a {310} plane or a {210} plane. For example, the D1 surface 241a may be a (130) plane, a (120) plane, or a (210) plane.

The seventh sub pattern 242 may be provided between the sixth sub pattern 241 and the second sub pattern 212. One end portion of the seventh sub pattern 242 may be connected to the sixth sub pattern 241 and the other end portion may be connected to the second sub pattern 212. The seventh sub pattern 242 may extend along a sixth direction DR6 crossing the first direction DR1, the second direction DR2, and the fifth direction DR5. The sixth direction DR6 may have a first direction DR1 component and a second direction DR2 component. When the magnitude of the first direction DR1 component in the sixth direction DR6 is equal to the magnitude of the first direction DR1 component in the fifth direction DR5, the magnitudes of the second direction DR2 component in the sixth direction DR6 may be greater than the magnitude of the second direction DR2 component. When the ratio between the magnitudes of the first direction DR1 component and the second direction DR2 component in the fifth direction DR5 is 3:1, the ratio between the magnitudes of the first direction DR1 component and the second direction DR2 component in the sixth direction DR6 may be 2:1, 1:2, or 1:3. When the ratio between the magnitudes of the first direction DR1 component and the second direction DR2 component in the fifth direction DR5 is 2:1, the ratio between the magnitudes of the first direction DR1 component and the second direction DR2 component in the sixth direction DR6 may be 1:2 or 1:3. When the ratio between the magnitudes of the first direction DR1 component and the second direction DR2 component in the fifth direction DR5 is 1:2, the ratio between the magnitudes of the first direction DR1 component and the second direction DR2 component in the sixth direction DR6 may be 1:3.

The seventh sub pattern 242 may have the first conductivity type. A channel connecting the first source/drain region SD1 and the second source/drain region SD2 may be formed in the seventh sub pattern 242 by a voltage applied to the gate electrode 220. The channel may be provided adjacent to the surface of the seventh sub pattern 242. The seventh sub pattern 242 may have an E1 surface 242a, an E2 surface 242b, and an E3 surface 242c. The E1 surface 242a, the E2 surface 242b, and the E3 surface 242c may extend along the sixth direction DR6. The E1 side 242a and the E2 side 242b may be both side surfaces of the seventh sub pattern 242 positioned opposite to each other. The E3 surface 242c may be a top surface of the seventh sub pattern 242. The E3 surface 242c may have substantially the same plane index as the first surface 100a. For example, the E3 surface 242c may be a (100) plane. The equivalent plane index of the E1 surface 242a may be determined to have a low interfacial trap density. For example, the E1 surface 242a may be a {210} plane or a {310} plane. For example, the E1 surface 241a may be a (120) plane, a (210) plane, or a (310) plane.

The gate electrode 220 may be provided on the sixth sub pattern 241 and the seventh sub pattern 242. The gate electrode 220 may be provided on the D1 surface 241a, the D3 surface 241c, the E1 surface 242a, and the E3 surface 242c. In a plan view, the gate electrode 220 may completely overlap the D1 surface 241a, the D3 surface 241c, the E1 surface 242a, and the E3 surface 242c. The gate insulating layer 230 may be provided between the gate electrode 220 and the sixth sub pattern 241 and between the gate electrode 220 and the seventh sub pattern 242. The gate insulating layer 230 may include an electrical insulating material. For example, the gate insulating layer 230 may include silicon oxide, silicon nitride, or silicon oxynitride. As the gate electrode 220 is provided on the D1 surface 241a, the D3 surface 241c, the E1 surface 242a, and the E3 surface 242c, the channel of the pixel transistor 200 may be formed on the D1 surface 241a, the D3 surface 241c, the E1 surface 242a, and the E3 surface 242c.

According to the present inventive concepts, the pixel 13 in which the charge trap phenomena is improved by using a surface having a low interfacial trap density (e.g., {310} plane, {210} plane) as a channel may be provided. Accordingly, the image sensor with improved noise characteristics may be provided.

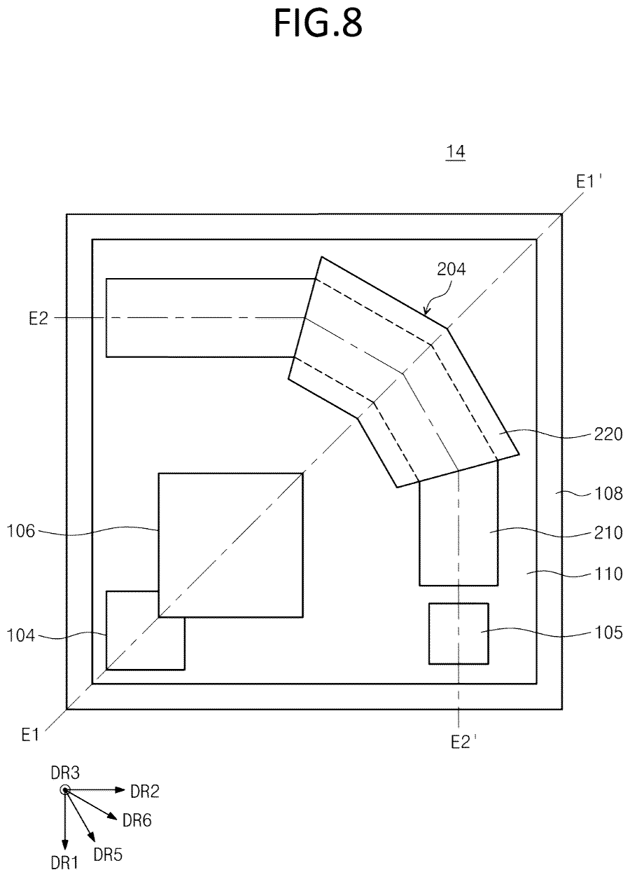

FIG. 8 is a plan view illustrating pixel of an image sensor according to example embodiments. A cross-sectional view taken along line E1-E1′ of FIG. 8 may be substantially the same as that of FIG. 5B. A cross-sectional view along line E2-E2′ of FIG. 8 may be substantially the same as that of FIG. 4C. For brevity of description, differences from the embodiment described with reference to FIG. 7A are described.

Referring to FIGS. 4C, 5B, and 8, unlike the description with reference to FIG. 7A, the gate electrode 220 and the gate insulating layer 230 may further extend onto the D2 surface 241b of the sixth sub pattern 241 and the E2 surface 242b of the seventh sub pattern 242 (e.g., see FIG. 7B). Equivalent plane indices of the D2 surface 241b and the E2 surface 242b may be determined to have a low interfacial trap density. The D2 surface 241b may be a {210} plane or a {310} plane. When the D1 surface 241a is a (210) plane, the D2 surface 241b may be a (2̅1̅0) plane. When the D1 surface 241a is a (120) plane, the D2 surface 241b may be a (1̅2̅0) plane. When the D1 surface 241a is a (130) plane, the D2 surface 241b may be a (1̅3̅0) plane. The E2 surface 242b may be a {210} plane or a {310} plane. When the E1 surface 242a is a (120) plane, the E2 surface 242b may be a (1̅2̅0) plane. When the E1 surface 242a is a (210) plane, the E2 surface 242b may be a (2̅1̅0) plane. When the E1 surface 242a is a (310) plane, the E2 surface 242b may be a (3̅1̅0) plane.

As the gate electrode 220 is provided on the D1 surface 241a, the D2 surface 241b, the D3 surface 241c, the E1 surface 242a, the E2 surface 242b, and the E3 surface 242c, a channel of the pixel transistor 200 may be formed in a region adjacent to the D1 surface 241a, the D2 surface 241b, the D3 surface 241c, the E1 surface 242a, the E2 surface 242b, and the E3 surface 242c.

According to example embodiments of the inventive concepts, the pixel 14 in which the charge trap phenomena is improved may be provided by using a surface having a low interfacial trap density (e.g., {310} plane, {210} plane) as a channel. Accordingly, the image sensor with improved noise characteristics may be provided.

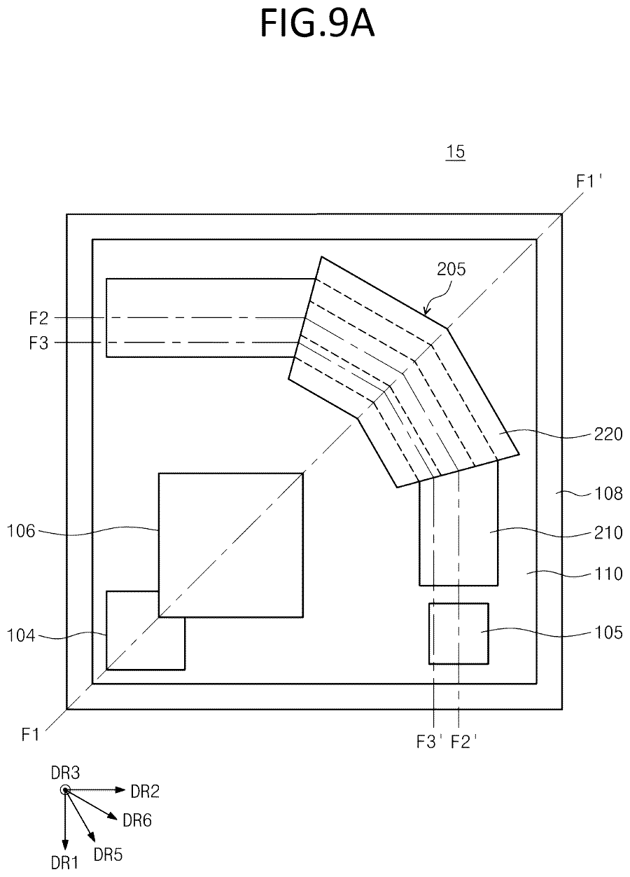

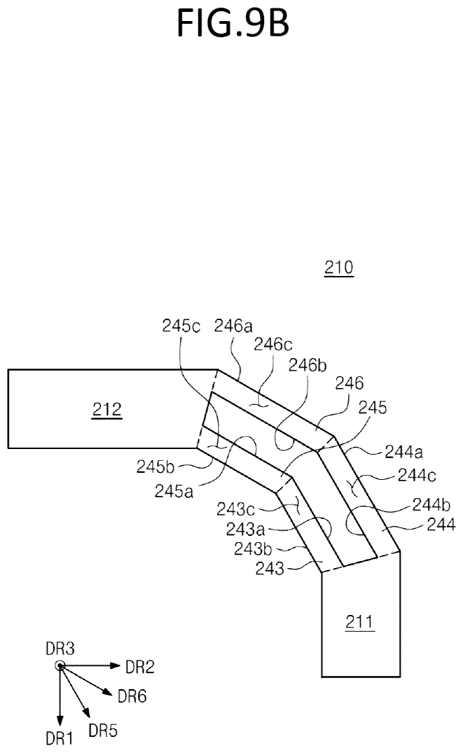

FIG. 9A is a plan view illustrating pixel of an image sensor according to example embodiments. FIG. 9B is a plan view illustrating the semiconductor pattern of FIG. 9A. A cross-sectional view along the line F1-F1′ of FIG. 9A may be substantially the same as that of FIG. 6B. A cross-sectional view along the line F2-F2′ of FIG. 9A may be substantially the same as that of FIG. 6C. A cross-sectional view taken along the line F3-F3′ of FIG. 9A may be substantially the same as that of FIG. 4C. For brevity of description, differences from the embodiment described with reference to FIG. 7A are described.

Referring to FIGS. 7B, 9A and 9B, unlike the description with reference to FIG. 7B, the semiconductor pattern 210 may include an eighth sub pattern 243 and a ninth sub pattern 244 instead of the sixth sub pattern 241 and may include a tenth sub pattern 245 and an eleventh sub pattern 246 instead of the seventh sub pattern 242. The eighth sub pattern 243 may be provided between the tenth sub pattern 245 and the first sub pattern 211. One end portion of the eighth sub pattern 243 may be connected to the first sub pattern 211 and the other end portion may be connected to the tenth sub pattern 245. The ninth sub pattern 244 may be provided between the eleventh sub pattern 246 and the first sub pattern 211. One end portion of the ninth sub pattern 244 may be connected to the first sub pattern 211 and the other end portion may be connected to the eleventh sub pattern 246. The eighth sub pattern 243 and the ninth sub pattern 244 may extend along the fifth direction DR5.

The tenth sub pattern 245 may be provided between the second sub pattern 212 and the eighth sub pattern 243. One end portion of the tenth sub pattern 245 may be connected to the eighth sub pattern 243 and the other end portion may be connected to the second sub pattern 212. The eleventh sub pattern 246 may be provided between the second sub pattern 212 and the ninth sub pattern 244. One end portion of the eleventh sub pattern 246 may be connected to the ninth sub pattern 244 and the other end portion may be connected to the second sub pattern 212. The tenth sub pattern 245 and the eleventh sub pattern 246 may extend along the sixth direction DR6.

The eighth to eleventh sub patterns 243, 244, 245, and 246 may have the first conductivity type. A channel connecting the first source/drain region SD1 and the second source/drain region SD2 may be formed in the eighth to eleventh sub patterns 243, 244, 245, and 246 by a voltage applied to the gate electrode 220. The channel may be provided adjacent to surfaces of the eighth to eleventh patterns 243, 244, 245, and 246. The eighth sub pattern 243 may have an F1 surface 243a, an F2 surface 243b, and an F3 surface 243c. The F1 surface 243a and the F2 surface 243b may be both side surfaces of the eighth sub pattern 243 positioned opposite to each other. The F3 surface 243c may be a top surface of the eighth sub pattern 243. The ninth sub pattern 244 may have a G1 surface 244a, a G2 surface 244b, and a G3 surface 244c. The G1 surface 244a and the G2 surface 244b may be both side surfaces of the ninth sub pattern 244 positioned opposite to each other. The G3 surface 244c may be a top surface of the ninth sub pattern 244. The F1 surface 243a and the G2 surface 244b may face each other.

The tenth sub pattern 245 may have an H1 surface 245a, an H2 surface 245b, and an H3 surface 245c. The H1 surface 245a and the H2 surface 245b may be both side surfaces of the tenth sub pattern 245 positioned opposite to each other. The H3 surface 245c may be a top surface of the tenth sub pattern 245. The eleventh sub pattern 246 may have an I1 surface 246a, an I2 surface 246b, and an I3 surface 246c. The 11 surface 246a and the I2 surface 246b may be both side surfaces of the eleventh sub pattern 246 positioned opposite to each other. The I3 surface 246c may be a top surface of the eleventh sub pattern 246. The H1 surface 245a and the I2 surface 246b may face each other.

The F3 surface 243c, the G3 surface 244c, the H3 surface 245c, and the 13 surface 246c may have substantially the same plane index as the first surface 100a. For example, the F3 surface 243c, the G3 surface 244c, the H3 surface 245c, and the I3 surface 246c may be (100) planes. The equivalent plane index of the F1 surface 243a, the F2 surface 243b, the G1 surface 244a, the G2 surface 244b, the H1 surface 245a, the H2 surface 245b, the I1 surface 246a, and the I2 surface 246b may be determined to have a low interfacial trap density. In example embodiments, the F1 surface 243a, the F2 surface 243b, the G1 surface 244a, and the G2 surface 244b may be a {310} plane. In example embodiments, the F1 surface 243a and the G1 surface 244a may be (130) planes, and the F2 surface 243b and G2 surface 244b may be (130) planes. A pair of the plane index of the H1 surface 245a and I1 surface 246a and the plane index of the H2 surface 245b and 12 surface 246B may be (310)-(3̅1̅0), (210)-(2̅1̅0), or (120)-(1̅2̅0). In example embodiments, the F1 surface 243a, the F2 surface 243b, the G1 surface 244a, and the G2 surface 244b may be a {210} planes. In example embodiments, the F1 surface 243a and the G1 surface 244a may be (120) planes, and the F2 surface 243b and G2 surface 244b may be (1̅2̅0) planes. A pair of the plane index of the H1 surface 245a and the I1 surface 246a and the plane index of the H2 surface 245b and the I2 surface 246b may be (310)-(3̅1̅0) or (210)-(2̅1̅0). In example embodiments, the F1 surface 243a and the G1 surface 244a may be (210) planes, and the F2 surface 243b and G2 surface 244b may be (2̅1̅0) planes. A pair of the plane index of the H1 surface 245a and the I1 surface 246a and the plane index of the H2 surface 245b and the I2 surface 246b may be (310)-(3̅1̅0).

The gate electrode 220 may be provided on the eighth to eleventh sub patterns 243, 244, 245, and 246. The gate electrode 220 may be configured to face the F1 surface 243a, the F2 surface 243b, the F3 surface 243c, the G1 surface 244a, the G2 surface 244b, the G3 surface 244c, the H1 surface 245a, and the H2 surface 245b, H2 surface 245b, I1 surface 246a, I2 surface 246b, and I3 surface 246c. A portion of the gate electrode 220 may extend to a region between the eighth sub pattern 243 and the ninth sub pattern 244 and a region between the tenth sub pattern 245 and the eleventh sub pattern 246.

The gate insulating layer 230 may be provided between the gate electrode 220 and the semiconductor pattern 210. For example, the gate insulating layer 230 may cover the F1 surface 243a, the F2 surface 243b, the F3 surface 243c, the G1 surface 244a, the G2 surface 244b, the G3 surface 244c, the H1 surface 245a, the H2 surface 245b, the H3 surface 245c, the I1 surface 246a, the I2 surface 246b, and the 13 surface 246c. The gate insulating layer 230 may electrically separate the semiconductor pattern 210 and the gate electrode 220. In example embodiments, the gate insulating layer 230 and the gate electrode 220 may be filled in a region between the eighth sub pattern 243 and the ninth sub pattern 244 and a region between the tenth sub pattern 245 and the eleventh sub pattern 246.

According to example embodiments of the inventive concepts, the pixel 15 in which the charge trap phenomena is improved by increasing an area of a surface having a low interfacial trap density (e.g., {310} plane, {210} plane) on which a channel is formed using the eighth to eleventh sub patterns 243, 244, 245, and 246 may be provided. Accordingly, an image sensor with improved noise characteristics may be provided.

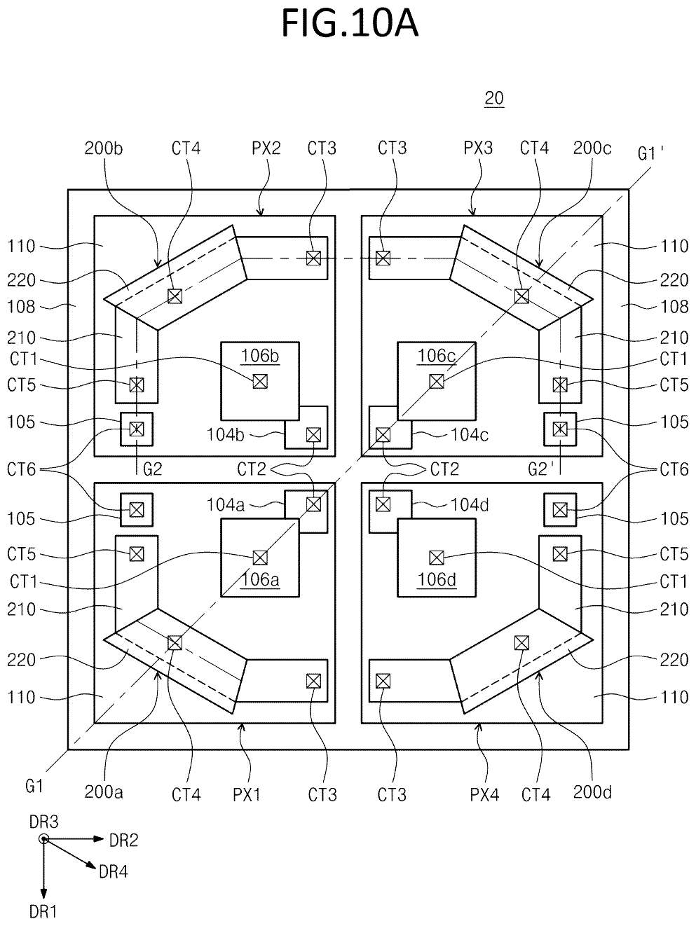

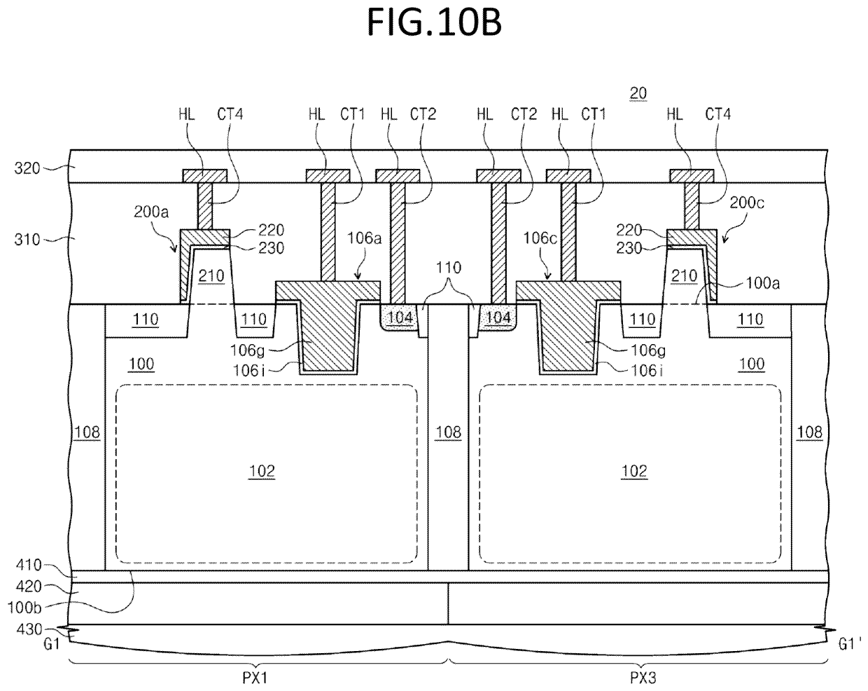

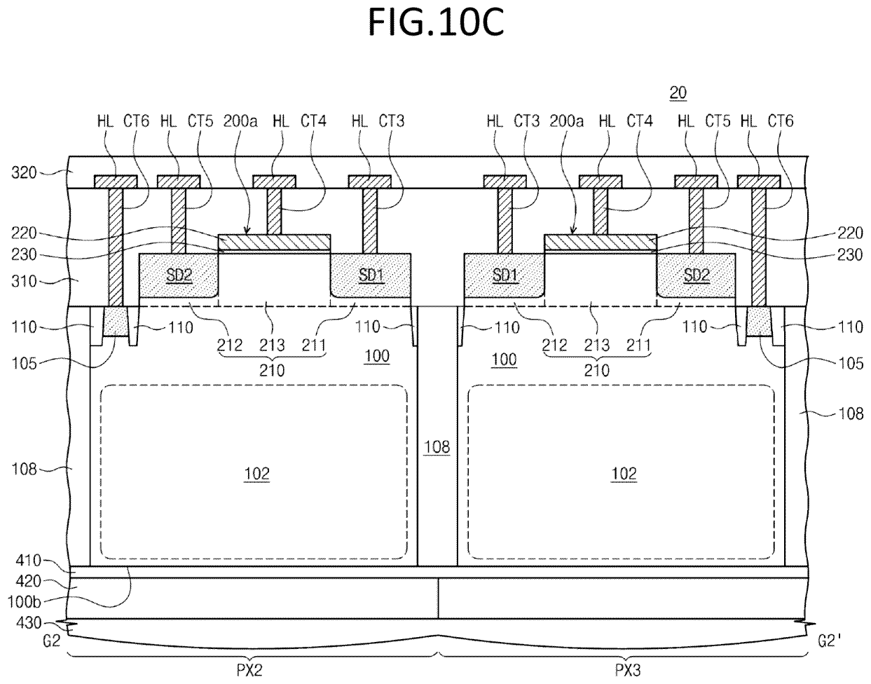

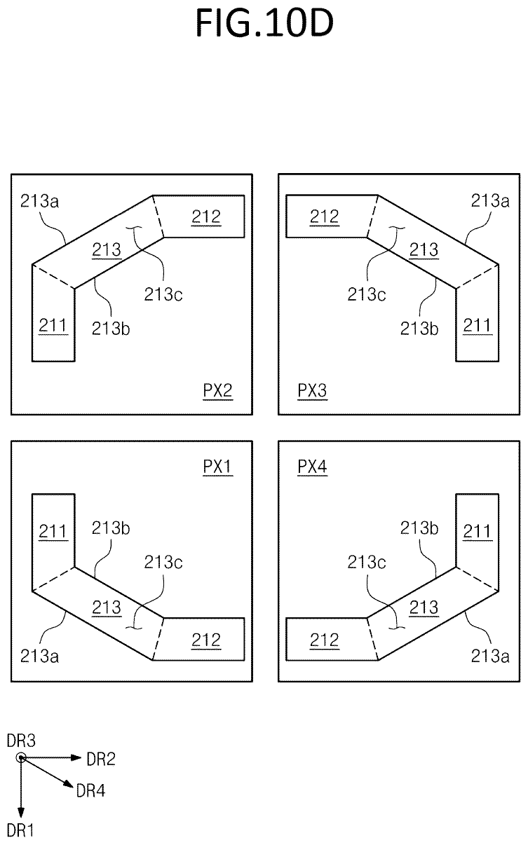

FIG. 10A is a plan view illustrating a pixel group of an image sensor according to example embodiments. FIG. 10B is a cross-sectional view taken along the line G1-G1′ of FIG. 10A. FIG. 10C is a cross-sectional view taken along line G2-G2′ of FIG. 10A. FIG. 10D is a plan view illustrating the semiconductor patterns of FIG. 10A. For brevity of description, content substantially the same as that described with reference to FIGS. 4A to 4D may not be described.

Referring to FIGS. 10A to 10D, a first pixel group 20 including a first pixel PX1, a second pixel PX2, a third pixel PX3, and a fourth pixel PX4 may be provided. The first pixel group 20 may be a set of pixels sharing a pixel transistor. For example, the first to fourth pixels PX1, PX2, PX3, and PX4 may share at least one of a source follower transistor, a reset transistor, and a selection transistor.

In a plan view, the first pixel PX1 may be substantially the same as the pixel 10 described with reference to FIGS. 4A to 4D rotated by 180 degrees (°). The second pixel PX2 may be substantially the same as the first pixel PX1 inverted along the arrangement direction of the first and second pixels PX1 and PX2 in a plane view. The third pixel PX3 may be substantially the same as the first pixel PX1 rotated by 180 degrees) (° in a plan view. The third pixel PX3 may be substantially the same as the pixel 10 described with reference to FIGS. 4A to 4D. The fourth pixel PX4 may be substantially the same as the first pixel PX1 inverted along the arrangement direction of the first and fourth pixels PX1 and PX4 in a plane view. As described above and hereinafter, a pixel being substantially the same as another pixel may for example mean that a layout of the pixel may be the same as a layout of the another pixel.

In example embodiments, the equivalent plane index of the A1 surfaces 213a and the A2 surfaces 213b of the first to fourth pixels PX1, PX2, PX3, and PX4 may be {310}. When the A1 surface 213a of the third pixel PX3 is a (310) plane, the A1 surfaces 213a of the first pixel PX1, the second pixel PX2, and the fourth pixel PX4 are respectively a (3̅1̅0) plane, a (3̅10) plane, and a (31̅0) plane. When the A2 surface 213b of the third pixel PX3 is a (3̅1̅0) plane, the A2 surfaces 213b of the first pixel PX1, the second pixel PX2, and the fourth pixel PX4 are respectively a (310) plane, a (31̅0) plane, and a (3̅10) plane. When the A1 surface 213a of the third pixel PX3 is a (130) plane, the A1 surfaces 213a of the first pixel PX1, the second pixel PX2, and the fourth pixel PX4 are respectively a (1̅3̅0) plane, a (1̅30) plane, and a (13̅0) plane. When the A2 surface 213b of the third pixel PX3 is a (1̅3̅0) plane, the A2 surface 213b of the first pixel PX1, the second pixel PX2, and the fourth pixel PX4 are respectively a (130) plane, a (13̅0) plane, and a (1̅30) plane.

In example embodiments, the equivalent plane index of the A1 surfaces 213a and the A2 faces 213b of the first to fourth pixels PX1, PX2, PX3, and PX4 may be {210}. When the A1 surface 213a of the third pixel PX3 is a (210) plane, the A1 surfaces 213a of the first pixel PX1, the second pixel PX2, and the fourth pixel PX4 are respectively a (2̅1̅0) plane, a (2̅10) plane, and a (21̅0) plane. When the A2 surface 213b of the third pixel PX3 is a (2̅1̅0) plane, the A2 surfaces 213b of the first pixel PX1, the second pixel PX2, and the fourth pixel PX4 are respectively a (210) plane, a (21̅0) plane, and a (2̅10) plane. When the A1 surface 213a of the third pixel PX3 is a (120) plane, the A1 surfaces 213a of the first pixel PX1, the second pixel PX2, and the fourth pixel PX4 are respectively a (1̅2̅0) plane, a (1̅20) plane, and a (12̅0) plane. When the A2 surface 213b of the third pixel PX3 is a (1̅2̅0) plane, the A2 surface 213b of the first pixel PX1, the second pixel PX2, and the fourth pixel PX4 are respectively a (120) plane, a (12̅0) plane, and a (1̅20) plane. Surfaces of the first to fourth pixels included in the second to seventh pixel groups described below may have plane indices according to the same rule as described above.

The first pixel PX1 and the second pixel PX2 may be spaced apart from each other along the first direction DR1. The first pixel PX1 and the fourth pixel PX4 may be spaced apart from each other along the second direction DR2. The third pixel PX3 may be spaced apart from the second pixel PX2 along the second direction DR2. The fourth pixel PX4 may be spaced apart from the third pixel PX3 along the first direction DR1. A pixel isolation layer 108 may be provided between the first to fourth pixels PX1, PX2, PX3, and PX4. The pixel isolation layer 108 may surround the first to fourth pixels PX1, PX2, PX3, and PX4, respectively.

An interlayer dielectric 310 may be provided on the substrate 100. The interlayer dielectric 310 may cover the pixel transistors 200a, 200b, 200c, and 200d. The interlayer dielectric 310 may include, for example, silicon oxide, silicon nitride, or silicon oxynitride.

First contacts CT1, second contacts CT2, third contacts CT3, fourth contacts CT4, fifth contacts CT5, and sixth contacts CT6 penetrating the interlayer dielectric 310 may be provided. The first contacts CT1, the second contacts CT2, the third contacts CT3, the fourth contacts CT4, the fifth contacts CT5, and the sixth contacts CT6 may extend along the third direction DR3. The first contacts CT1 may be electrically connected to the transfer gate electrodes 106g, respectively. The second contacts CT2 may be electrically connected to the floating diffusion regions 104a, 104b, 104c, and 104d, respectively. The third contacts CT3 may be electrically connected to the first source/drain regions SD1, respectively. The fourth contacts CT4 may be electrically connected to the gate electrodes 220, respectively. The fifth contacts CT5 may be electrically connected to the second source/drain regions SD2, respectively. The sixth contacts CT6 may be electrically connected to the ground regions 105, respectively. The first to sixth contacts CT1-CT6 may be electrically connected to the horizontal conductive lines HL, respectively. Although it is shown that one contact and one horizontal conductive line are connected, in example embodiments the number of contacts and horizontal conductive lines can be implemented as desired. For example, a plurality of contacts and a plurality of horizontal conductive lines may be alternately connected.

A capping insulating layer 320 may be provided on the interlayer dielectric 310. The capping insulating layer 320 may be configured to cover the horizontal conductive lines HL and protect the horizontal conductive lines HL. The capping insulating layer 320 may include, for example, silicon oxide, silicon nitride, or silicon oxynitride.

A backside insulating layer 410 may be provided on the second surface 100b. The backside insulating layer 410 may include, for example, silicon oxide, silicon nitride, or silicon oxynitride.

A color filter 420 may be provided on the backside insulating layer 410. The color filter 420 may be provided to correspond to the photoelectric conversion region PD. The color filters 420 may be included in an array of color filters 420 arranged in a matrix form. In example embodiments, the array of color filters 420 may have a Bayer pattern including a red filter, a green filter, and a blue filter. In example embodiments, the array of color filters 420 may include a yellow filter, a magenta filter, and a cyan filter. Also, the array of color filters 420 may additionally include a white filter. Meanwhile, according to an embodiment, an antireflection layer, at least one insulating layer, or the like may be further formed between the second surface 100b of the semiconductor substrate 100 and the color filter 420.

A microlens 430 may be provided on the color filter 420. The microlens 430 may be configured such that incident light incident on the microlens 430 is focused on the photoelectric conversion region PD. The microlens 430 may be included in a microlens array arranged in a matrix form. Although one microlens 430 is illustrated as being disposed per pixel, in example embodiments the microlenses 430 may be disposed in plural one by one in a plurality of pixels.

According to example embodiments of the inventive concepts, the pixel groups 20 in which the charge trap phenomena is improved by using a surface having a low interfacial trap density (e.g., {310} plane, {210} plane) as a channel may be provided. Accordingly, the image sensor with improved noise characteristics may be provided.

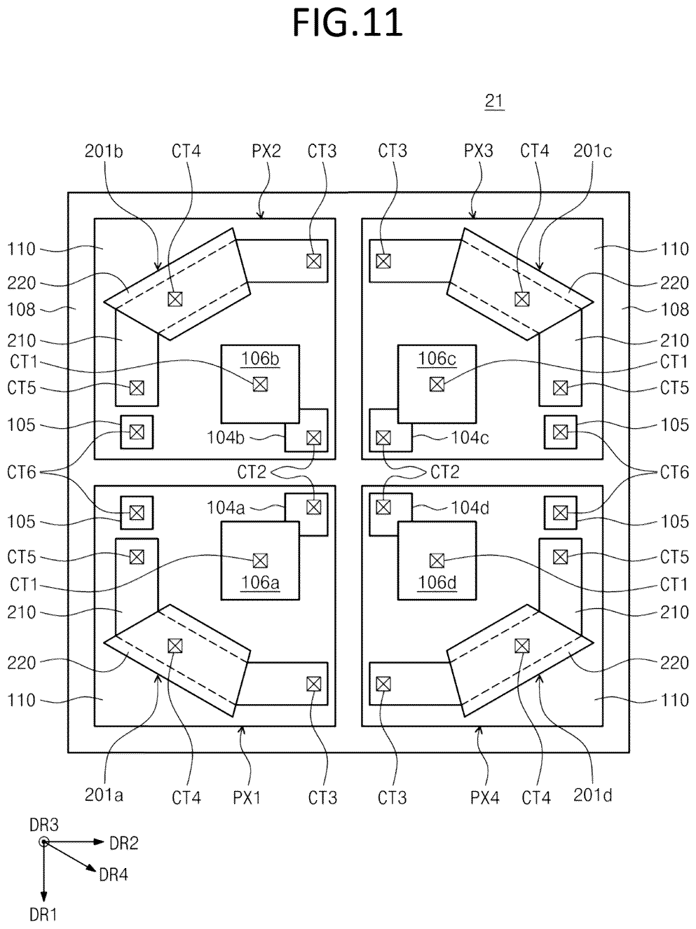

FIGS. 11 to 15 are plan views illustrating pixel groups of an image sensor according to example embodiments. For brevity of description, differences from the embodiment described with reference to FIGS. 10A to 10D are mainly described.

Referring to FIGS. 11 to 15, a second pixel group 21, a third pixel group 22, a fourth pixel group 23, a fifth pixel group 24, and a sixth pixel group 25 including a first pixel PX1, a second pixel PX2, a third pixel PX3, and a fourth pixel PX4 may be provided.

In the second pixel group 21 of FIG. 11, the first pixel PX1 may be substantially the same as the pixel 11 described with reference to FIGS. 5A and 5B rotated by 180 degrees (°) in a plan view. The second pixel PX2 may be substantially the same as the first pixel PX1 inverted along the arrangement direction of the first and second pixels PX1 and PX2 in a plan view. The third pixel PX3 may be substantially the same as the first pixel PX1 rotated by 180 degrees (°) in a plan view. The third pixel PX3 may be substantially the same as the pixel 11 described with reference to FIGS. 5A and 5B. The fourth pixel PX4 may be substantially the same as the first pixel PX1 inverted along the arrangement direction of the first and fourth pixels PX1 and PX4 in a plan view.

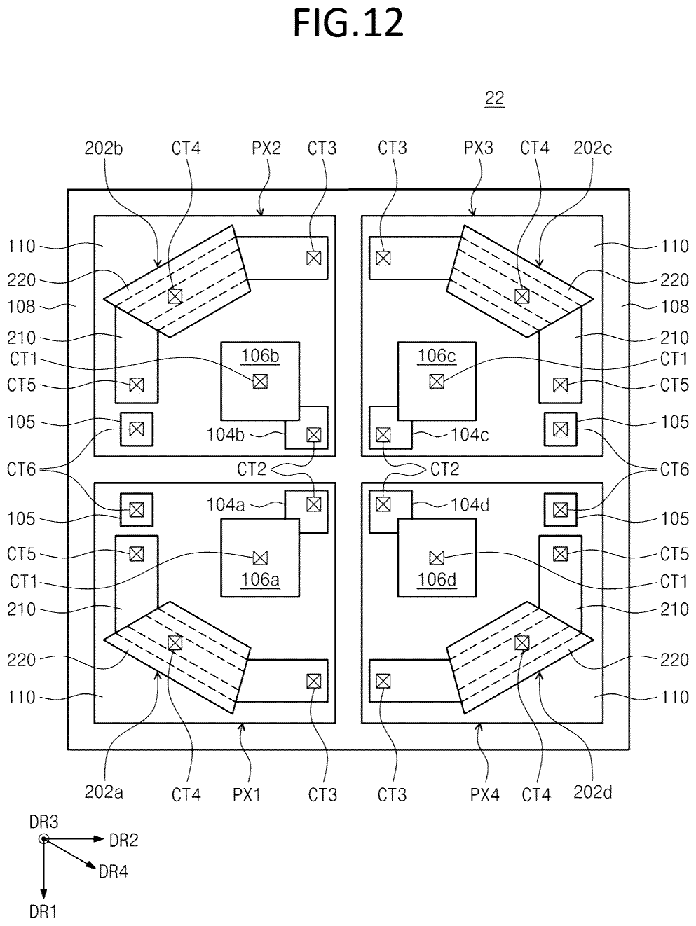

In the third pixel group 22 of FIG. 12, the first pixel PX1 may be substantially the same as the pixel 12 described with reference to FIGS. 6A to 6D rotated by 180 degrees (°) in a plan view. The second pixel PX2 may be substantially the same as the first pixel PX1 inverted along the arrangement direction of the first and second pixels PX1 and PX2 in a plan view. The third pixel PX3 may be substantially the same as the first pixel PX1 rotated by 180 degrees (°) in a plan view. The third pixel PX3 may be substantially the same as the pixel 12 described with reference to FIGS. 6A to 6D. The fourth pixel PX4 may be substantially the same as the first pixel PX1 inverted along the arrangement direction of the first and fourth pixels PX1 and PX4 in a plan view.

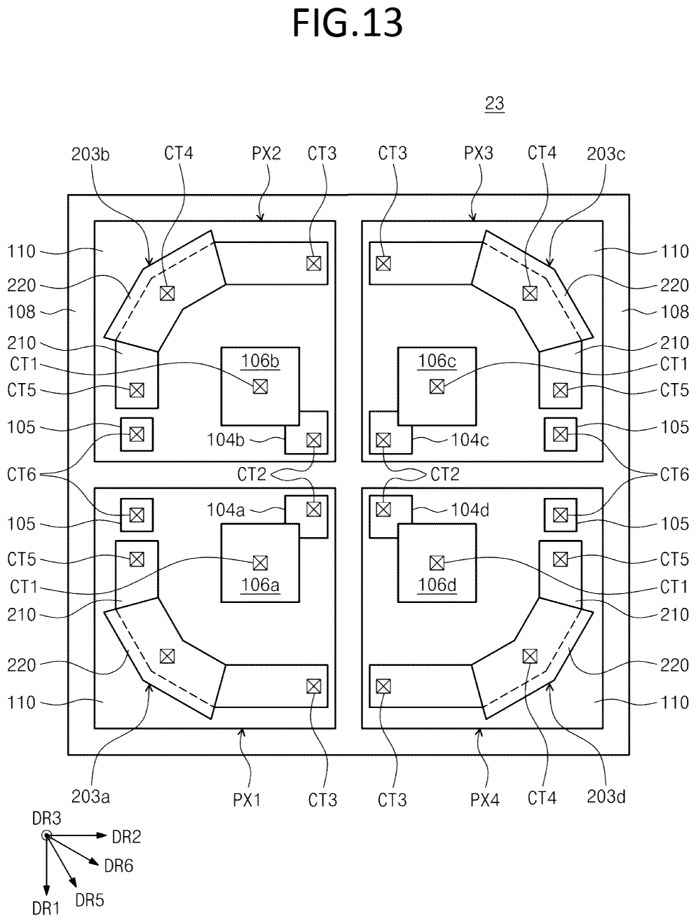

In the fourth pixel group 23 of FIG. 13, the first pixel PX1 may be substantially the same as the pixel 13 described with reference to FIGS. 7A and 7B rotated by 180 degrees (°) in a plan view. The second pixel PX2 may be substantially the same as the first pixel PX1 inverted along the arrangement direction of the first and second pixels PX1 and PX2 in a plan view. The third pixel PX3 may be substantially the same as the first pixel PX1 rotated by 180 degrees (°) in a plan view. The third pixel PX3 may be substantially the same as the pixel 13 described with reference to FIGS. 7A and 7B. The fourth pixel PX4 may be substantially the same as the first pixel PX1 inverted along the arrangement direction of the first and fourth pixels PX1 and PX4 in a plan view.

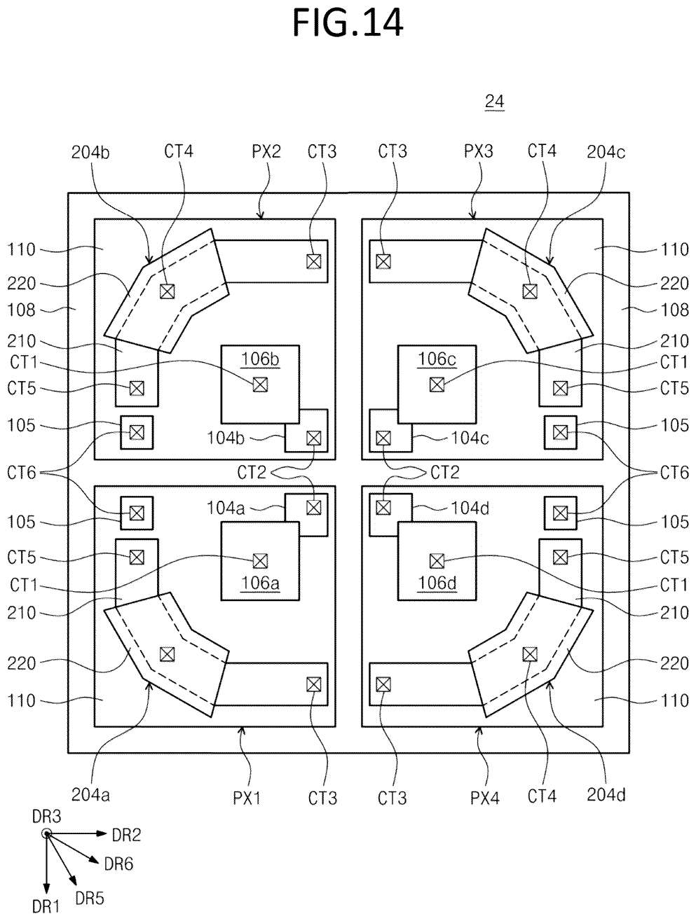

In the fifth pixel group 24 of FIG. 14, the first pixel PX1 may be substantially the same as the pixel 14 described with reference to FIG. 8 rotated by 180 degrees (°) in a plan view. The second pixel PX2 may be substantially the same as the first pixel PX1 inverted along the arrangement direction of the first and second pixels PX1 and PX2 in a plan view. The third pixel PX3 may be substantially the same as the first pixel PX1 rotated by 180 degrees (°) in a plan view. The third pixel PX3 may be substantially the same as the pixel 14 described with reference to FIG. 8. The fourth pixel PX4 may be substantially the same as the first pixel PX1 inverted along the arrangement direction of the first and fourth pixels PX1 and PX4 in a plan view.

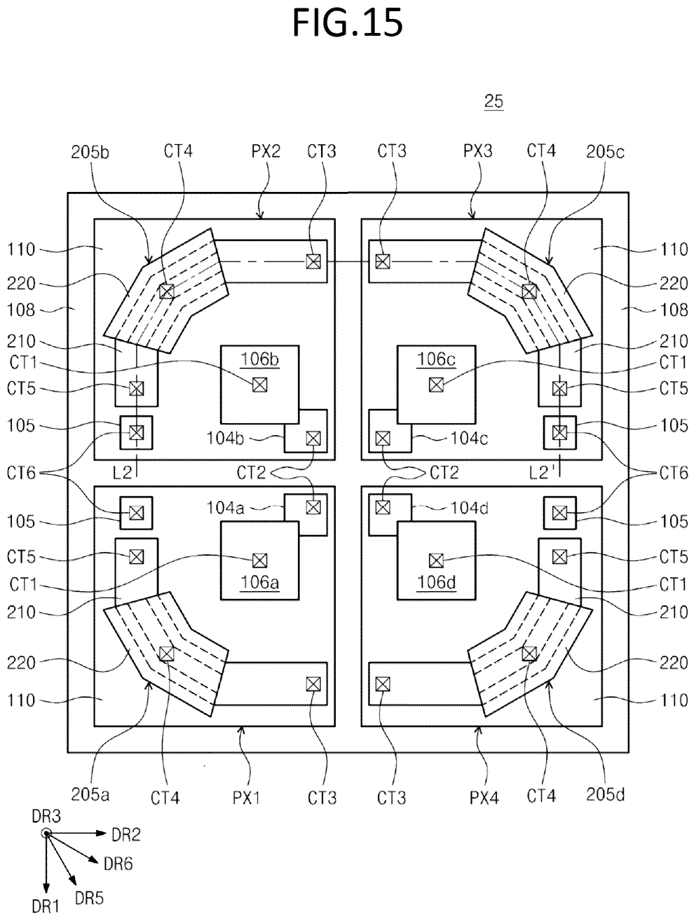

In the sixth pixel group 25 of FIG. 15, the first pixel PX1 may be substantially the same as the pixel 15 described with reference to FIGS. 9A and 9B rotated by 180 degrees (°) in a plan view. The second pixel PX2 may be substantially the same as the first pixel PX1 inverted along the arrangement direction of the first and second pixels PX1 and PX2 when viewed in a plan view. The third pixel PX3 may be substantially the same as the first pixel PX1 rotated by 180 degrees (°) in a plan view. The third pixel PX3 may be substantially the same as the pixel 15 described with reference to FIGS. 9A and 9B. The fourth pixel PX4 may be substantially the same as the first pixel PX1 inverted along the arrangement direction of the first and fourth pixels PX1 and PX4 in a plan view.

According to example embodiments of the inventive concepts, the pixel groups 21, 22, 23, 24, and 25 as respectively shown in FIGS. 11-15 in which the charge trap phenomena is improved by using a surface having a low interfacial trap density (eg, {310} plane, {210} plane) as a channel may be provided. Accordingly, the image sensor with improved noise characteristics may be provided.

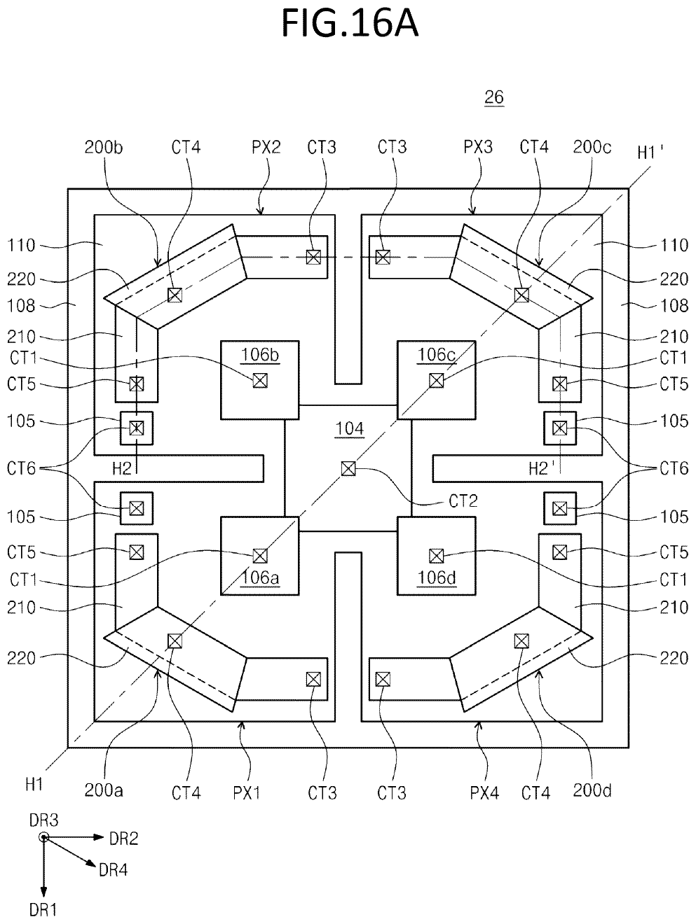

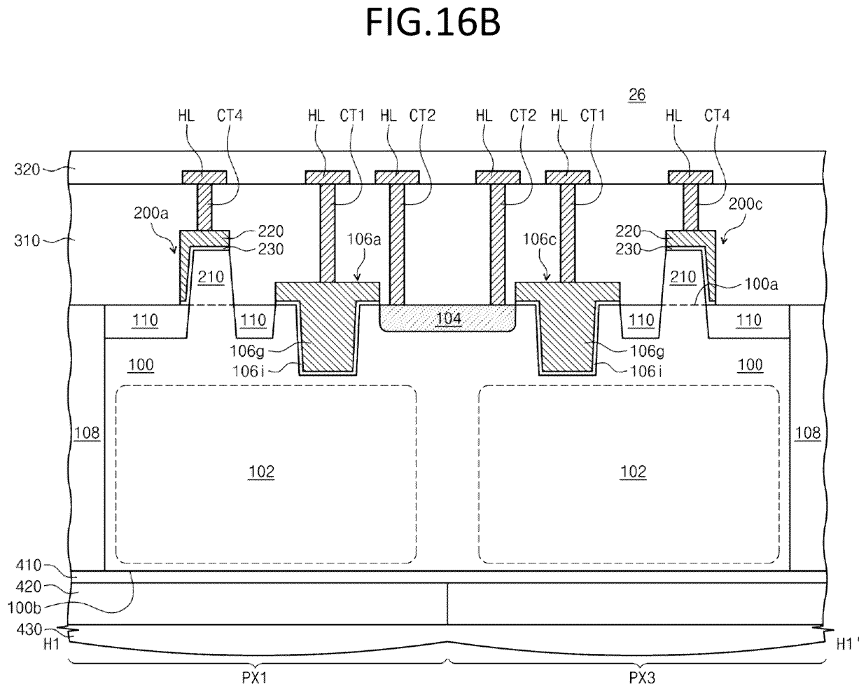

FIG. 16A is a plan view illustrating a pixel group of an image sensor according to example embodiments. FIG. 16B is a cross-sectional view taken along the line H1-H1′ of FIG. 16A. A cross-sectional view taken along line H2-H2′ of FIG. 16A may be substantially the same as that of FIG. 10C. For brevity of description, content substantially the same as that described with reference to FIGS. 10A to 10D may not be described.

Referring to FIGS. 16A and 16B, a seventh pixel group 26 including a first pixel PX1, a second pixel PX2, a third pixel PX3, and a fourth pixel PX4 may be provided. Unlike the description with reference to FIGS. 10A to 10D, the first to fourth pixels PX1, PX2, PX3, and PX4 may share the floating diffusion region 104. The floating diffusion region 104 may be provided between the first to fourth pixels PX1, PX2, PX3, and PX4. For example, the floating diffusion region 104 may be located at the center of the first to fourth pixels PX1, PX2, PX3, and PX4. However, different from the illustrated location and shape of the floating diffusion region 104 as shown in FIG. 16A, the location and shape of the floating diffusion region may be implemented differently as desired.

In a plan view, the substrate 100 may surround the floating diffusion region 104. The substrate 100 of the first pixel PX1 and the substrate 100 of the second pixel PX2, the substrate 100 of the first pixel PX1 and the substrate 100 of the fourth pixel PX4, the substrate 100 of the second pixel PX2 and the substrate 100 of the third pixel PX3, and the substrate 100 of the third pixel PX3 and the substrate 100 of the fourth pixel PX4 may be connected to each other.

The pixel isolation layer 108 may fill an area between the first to fourth pixels PX1, PX2, PX3, and PX4. Unlike the description with reference to FIGS. 10A to 10D, the pixel isolation layer 108 may partially surround each of the first to fourth pixels PX1, PX2, PX3, and PX4.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to example embodiments of the inventive concepts, the pixel group 26 in which the charge trap phenomena is improved by using a surface having a low interfacial trap density (e.g., {310} plane, {210} plane) as a channel may be provided. Accordingly, an image sensor with improved noise characteristics may be provided.

According to example embodiments of the present disclosure, a pixel with improved trap characteristics may be provided, and an image sensor having improved noise characteristics may thus be provided.

While the present disclosure has been described with reference to example embodiments thereof, it will be apparent to those of ordinary skill in the art that various changes and modifications may be made thereto without departing from the spirit and scope of the present disclosure as set forth in the following claims.

What is claimed is:

1. An image sensor comprising:
a substrate including a photoelectric conversion region;
a semiconductor pattern on the substrate;
a gate electrode on the semiconductor pattern; and
a gate insulating layer between the semiconductor pattern and the gate electrode,
wherein the semiconductor pattern includes a first sub pattern including a first source/drain region, a second sub pattern including a second source/drain region, and a third sub pattern between the first sub pattern and the second sub pattern,
the gate electrode is on the third sub pattern, and
the first sub pattern, the second sub pattern, and the third sub pattern extend along different directions.

2. The image sensor of claim 1, wherein the gate electrode extends on a first side of the third sub pattern.

3. The image sensor of claim 2, wherein the first side is a {310} plane or a {210} plane.

4. The image sensor of claim 2, wherein the gate electrode extends on a second side of the third sub pattern that is opposite to the first side.

5. The image sensor of claim 4, wherein the first side and the second side are a {310} plane or a {210} plane.

6. The image sensor of claim 1, wherein the first sub pattern extends along a first direction,
the second sub pattern extends along a second direction perpendicular to the first direction,
the third sub pattern extends along a third direction crossing the first and second directions, and
a ratio between a magnitude of a first direction component and a magnitude of a second direction component of the third direction is 1:3, 1:2, 2:1, or 3:1.

7. The image sensor of claim 1, wherein the semiconductor pattern further includes a fourth sub pattern between the second sub pattern and the third sub pattern,
the gate electrode is on the fourth sub pattern, and
the fourth sub pattern extends in a direction different from the directions of the first sub pattern, the second sub pattern, and the third sub pattern.

8. The image sensor of claim 7, the gate electrode extends on a first side of the fourth sub pattern.

9. The image sensor of claim 8, the gate electrode extends on a second side of the fourth sub pattern that is opposite to the first side.

10. The image sensor of claim 9, wherein the first side and the second side are a {310} plane or a {210} plane.

11. The image sensor of claim 7, wherein the first sub pattern extends along a first direction,
the second sub pattern extends along a second direction perpendicular to the first direction,
the third sub pattern and the fourth sub pattern extend respectively along a third direction and a fourth direction crossing the first and second directions,
a ratio of a magnitude of a component along the first direction of the third direction to a magnitude of a component along the second direction of the third direction is 1:2, 2:1, or 3:1, and
a ratio of a magnitude of a component along the first direction of the fourth direction to a magnitude of a component along the second direction of fourth direction is 1:3, 1:2, or 2:1.

12. The image sensor of claim 7, wherein the semiconductor pattern further includes a fifth sub pattern between the first sub pattern and the second sub pattern,
the fifth sub pattern is arranged side by side with the third sub pattern, and
the gate electrode is on the fifth sub pattern.

13. The image sensor of claim 12, wherein the third sub pattern has a first side and a second side that are opposite to each other,
the fifth sub pattern has a third side and a fourth side that are opposite to each other, and
the gate electrode extends on the first side, the second side, the third side, and the fourth side.

14. The image sensor of claim 13, wherein the first side, the second side, the third side, and the fourth side are {310} planes or {210} planes.

15. The image sensor of claim 1, wherein the substrate further comprises a floating diffusion region spaced apart from the photoelectric conversion region, and a transfer gate structure extending from a region adjacent to the floating diffusion region to a region adjacent to the photoelectric conversion region, and
the floating diffusion region is electrically connected to the gate electrode.

16. An image sensor comprising:
a first pixel; and
a second pixel,
wherein each of the first and second pixels includes a substrate including a photoelectric conversion region and a floating diffusion region, a semiconductor pattern on the substrate, a gate electrode on the semiconductor pattern, and a gate insulating layer between the semiconductor pattern and the gate electrode,
the semiconductor pattern of each of the first and second pixels includes a first sub pattern including a first source/drain region, a second sub pattern including a second source/drain region, and a third sub pattern between the first sub pattern and the second sub pattern,
the first sub pattern, the second sub pattern, and the third sub pattern extend in different directions,
the gate electrode is on a side of the third sub pattern,
the floating diffusion region of the first and second pixels are electrically connected respectively to the gate electrode of the first pixel and the gate electrode of the second pixel.

17. The image sensor of claim 16, wherein a layout of the semiconductor pattern of the second pixel is the same as a layout of the semiconductor pattern of the first pixel inverted along an arrangement direction of the first pixel and the second pixel in plan view.

18. The image sensor of claim 16, wherein a layout of the semiconductor pattern of the second pixel is the same as a layout of the semiconductor pattern of the first pixel rotated by 180 degrees in plan view.

19. The image sensor of claim 16, wherein the first pixel and the second pixel share a same floating diffusion region.

20. The image sensor of claim 16, further comprising:
a third pixel; and
a fourth pixel,
wherein each of the third and fourth pixels includes a second substrate including a second photoelectric conversion region and a second floating diffusion region, a second semiconductor pattern on the second substrate, a second gate electrode on the second semiconductor pattern, and a second gate insulating layer between the second semiconductor pattern and the second gate electrode,
the second semiconductor pattern of each of the third and fourth pixels includes a fourth sub pattern including a third source/drain region, a fifth sub pattern including a fourth source/drain region, and a sixth sub pattern between the fourth sub pattern and the fifth sub pattern,
the fourth sub pattern, the fifth sub pattern, and the sixth sub pattern extend in different directions,
the second gate electrode is on a side of the sixth sub pattern,
the second floating diffusion region of the third and fourth pixels are electrically connected to the gate electrode of the first pixel or the gate electrode of the second pixel to which the floating diffusion region of the first and second pixels are electrically connected.
